(19) United States
(12) Patent Application Publication
(10) Pub. No.: US 2007/0211829 A1
(43) Pub. Date: Sep. 13, 2007

(54) Method and apparatus for pulse optimization for non-linear filtering

(75) Inventors: Paul Cheng-Po Liang, Santa Clara, CA (US); Stephan V. Schell, San Mateo, CA (US)

Correspondence Address: PATENT LAW PROFESSIONALS, P.O. BOX 612407, SAN JOSE, CA, 95161, US

(73) Assignee: Matsushita Electric Industrial Co., Ltd.

(21) Appl. No.: 11/591,702

(22) Filed: Nov. 2, 2006

Related U.S. Application Data
(63) Continuation-in-part of application No. 11/442,488, filed on May 26, 2006.
Application No. 11/442,488 is a continuation of application No. 10/037,870, filed on Oct. 22, 2001, now Pat. No. 7,054,385.

(51) Int. Cl. H03D 1/24

(52) U.S. Cl. 375/320

(57) ABSTRACT

Methods and apparatus for reducing signal degradation of a communications signal caused by reducing the average-to-minimum amplitude ratio (AMR) of a communications signal. According to one exemplary method, times when the amplitude of a communications signal falls below or is likely to fall below a predetermined magnitude minimum. Corrective pulses are generated, which are combined with the communications signal in the temporal vicinities when the amplitude of the communications signal falls below the predetermined magnitude minimum, to reduce the AMR of the communications signal. The corrective pulses are generated by a nonlinear filter that is configured to minimize the amount of in-channel distortion the corrective pulses introduce to the communications signal by their insertion while substantially preserving an out-of-band measure of quality of the communications signal.

### CROSS-REFERENCE TO RELATED APPLICATIONS

This application is a continuation-in-part of U.S. patent application Ser. No. 11/442,488, filed on May 26, 2006, which is a continuation of U.S. patent application Ser. No. 10/037,870, filed on Oct. 22, 2001, both applications which are hereby incorporated by reference.

### FIELD OF THE INVENTION

The present invention relates to the reduction of average-to-minimum power ratio in communications signals.

### STATE OF THE ART

Many modern digital radio communication systems transmit information by varying both the magnitude and phase of an electromagnetic wave. The process of translating information into the magnitude and phase of the transmitted signal is typically referred to as modulation. Many different modulation techniques are used in communication systems. The choice of modulation technique is typically influenced by the computational complexity needed to generate the signal, the characteristics of the radio channel, and, in mobile radio applications, the need for spectral efficiency, power efficiency and a small form factor. Once a modulation technique has been selected for some specific application, it is oftentimes difficult or essentially impossible to change the modulation. For example, in a cellular radio application all users would be required to exchange their current mobile phone for a new phone designed to work with the new modulation technique. Clearly this is not practical.

Many existing modulation formats have been designed to be transmitted with. radios that process the signal in rectangular coordinates. The two components in the rectangular coordinate system are often referred to as the in-phase and quadrature (I and Q) components. Such a transmitter is often referred to as a quadrature modulator. (A distinction is drawn between a modulation, which is a mathematical description of the method used to translate the information into the transmitted radio signal (e.g., BPSK, FSK, GMSK), and a modulator, which is the physical device used to perform this operation.) As an alternative, the transmitter may process the signal in polar coordinates, in which case the signal is represented in terms of its magnitude and phase. In this case the transmitter is said to employ a polar modulator. A polar modulator can have several performance advantages over the more conventional quadrature modulator, including higher signal fidelity, better spectral purity, and lower dependence of device performance on temperature variation.

Although a polar modulator can have practical advantages over a quadrature modulator, the magnitude and phase components of the signal typically have much higher bandwidth than the in-phase and quadrature components. This bandwidth expansion has implications for digital processing of the magnitude and phase, since the rate at which the magnitude and phase must be processed is dependent on their bandwidth.

The rate at which the magnitude and phase varies is very much dependent on the modulation technique. In particular, modulation formats that lead to very small magnitude values (relative to the average magnitude value) generally have very large phase component bandwidth. In fact, if the signal magnitude goes to zero, the signal phase can instantaneously change by up to 180 degrees. In this case the bandwidth of the phase component is essentially infinite, and the signal is not amenable to transmission by a polar modulator.

Many commonly employed modulation techniques do in fact lead to very small relative signal magnitude. To be more precise, the average-to-minimum signal magnitude ratio (AMR) is large. An important practical example of a modulation technique with large AMR is the technique employed in the UMTS 3GPP uplink (mobile-to-basestation).

Prior work in the field may be classified into two categories: one that deals generally with the reduction of peak power, and another that deal specifically with “hole-blowing.” Hole-blowing refers to the process of removing low-power events in a communication signal that has a time-varying envelope. This name arises in that, using this technique, a “hole” appears in the vector diagram of a modified signal.

Much work has been done dealing with peak power reduction, in which the goal is to locally reduce signal power. By contrast, relatively little work appears to have been done that deals with hole-blowing (which seeks to locally increase signal power), and prior approaches have been found to result in less-than-desired performance.

U.S. Pat. No. 5,805,640 (the '640 patent) entitled “Method and apparatus for conditioning modulated signal for digital communications,” together with U.S. Pat. No. 5,696,794 (the '794 patent), entitled “Method and apparatus for conditioning digitally modulated signals using channel symbol adjustment,” both describe approaches for removing low magnitude (low power) events in communication signals. Both patents in fact refer to creating “holes” in the signal constellation. The motivation given for creating these holes is that certain power amplifiers, in particular LINC power amplifiers, are difficult to implement when the signal amplitude dynamic range is large.

Briefly, the '794 patent teaches modifying the magnitude and phase of the symbols to be transmitted in order to maintain some minimum power. Since the symbols are modified before pulse shaping, the modified signal has the same spectral properties as the original signal. The approach used in the '640 patent is to add a pulse having a certain magnitude and phase in between the original digital symbols before pulse shaping. Hence, whereas in the former patent data is processed at the symbol rate (T=1), in the latter patent, data is processed at twice the symbol rate (T=2). For brevity, these two methods will be referred to as the symbol rate method and the T/2 method, respectively. The method used to calculate the magnitude and phase of the corrective pulse(s) is nearly identical in both patents.

Because the method used by both of these patents to calculate the corrective magnitude and phase is only a very rough approximation, performance is less than desired. More particularly, after processing the signal using either of these two approaches, the probability of a low power event is reduced, but remains significantly higher than desired.

The specific approach used in the T/2 method is to add a pulse having a prescribed magnitude and phase to the signal at half-symbol timing (i.e., at t=k*T+T/2) before pulse shaping. The magnitude and phase of the additive pulse is designed to keep the signal magnitude from dropping below some desired threshold. The method does not allow for placement of pulses at arbitrary timing. As a result, effectiveness is decreased, and EVM (error vector magnitude) suffers.

The method used in the T/2 approach to calculate the magnitude and phase and of the additive pulse is very restrictive in that:

1) The signal envelope is only tested for a minimum value at half-symbol timing (t=i*T+T/2).

2) The phase of the correction is not based on the signal envelope, but rather only on the two symbols adjoining the low-magnitude event.

These two restrictions can lead to errors in the magnitude and phase of the corrective pulses. Specifically, the true signal minimum may occur not at T/2, but at some slightly different time, so that error will be introduced into the magnitude of the corrective pulses. The validity of this assumption is very much dependent on the specific signal modulation and pulse-shape. For example, this may be a reasonable assumption for a UMTS uplink signal with one DPDCH, but is not a reasonable assumption for a UMTS uplink signal with two DPDCH active. The size of this magnitude error can be quite large. For example, in some cases the magnitude at T/2 is very near the desired minimum magnitude, but the true minimum is very close to zero. In such cases the calculated correction magnitude is much smaller than would be desired, which in turn results in the low-magnitude event not being removed.

The signal envelope at T/2 may be greater than the desired minimum, but the signal magnitude may be below the threshold during this inter-symbol time interval, so that a low-magnitude event may be missed entirely.

In any event, the correction magnitude obtained is often far from what is needed.

The method used to calculate the corrective phase essentially assumes that the phase of the pulse shaped waveform at T/2 will be very close to the phase of straight line drawn between the adjoining symbols. This is an approximation in any case (although generally a reasonable one), which will introduce some error in the phase. However, this approximation is only valid if the origin does not lie between the previously described straight line and the true signal envelope. When this assumption is violated, the corrective phase will be shifted by approximately 180 degrees from the appropriate value. This typically leaves a low-magnitude event that is not corrected.

While the T/2 method adds pulses at half-symbol timing, the symbol rate method adds pulses to the two symbols that adjoin a low-magnitude event. That is, if the signal has a low-magnitude event at t=kT+T/2, then symbols k and (k+1) will be modified. Both methods calculate the phase of the additive pulses the same way, and both methods test for a low-magnitude event in the same way, i.e., the signal envelope at half-symbol timing is tested. Therefore the same sources of magnitude error and phase error previously noted apply equally to this method.

The T/2 method applies the correction process repeatedly in an iterative fashion. That is, this method is applied iteratively “until there are no symbol interval minima less than the minimum threshold”.

As compared to the foregoing methods, U.S. Pat. No. 5,727,026, “Method and apparatus for peak suppression using complex scaling values,” addresses a distinctly different problem, namely reducing the Peak-to-Average power Ratio (PAR) of a communication signal. Large PAR is a problem for many, if not most, conventional power amplifiers (PA). A signal with a large PAR requires highly linear amplification, which in turn affects the power efficiency of the PA. Reduction is accomplished by adding a pulse to the original pulse-shaped waveform, with the pulse having an appropriate magnitude and phase such that the peak power is reduced. The pulse can be designed to have any desired spectral characteristics, so that the distortion can be kept in-band (to optimize ACPR), or allowed to leak somewhat out-of-band (to optimize EVM). The timing of the added pulse is dependent on the timing of the peak power, and is not constrained to lie at certain timing instants.

More particularly, this peak-reduction method adds a low-bandwidth pulse to the original (high PAR) signal. The added pulse is 180 degrees out of phase with the signal at the peak magnitude, and the magnitude of the additive pulse is the difference between the desired peak value and the actual peak value. Because the pulse is added to the signal (a linear operation) the spectral properties of the additive pulse completely determine the effect of the peak reduction technique on the signal spectrum. The possibility is addressed of a peak value occurring at some time that does not correspond to a sampling instant. The method emphasizes the ability to control the amount of signal splatter and/or signal distortion.

U.S. Pat. No. 6,175,551 also describes a method of PAR reduction, particularly for OFDM and multi-code CDMA signals where “a time-shifted and scaled reference function is subtracted from a sampled signal interval or symbol, such that each subtracted reference function reduces the peak power”. The reference function is a windowed sinc function in the preferred embodiment, or some other function that has “approximately the same bandwidth as the transmitted signal”.

Other patents of interest include U.S. Pat. Nos. 5,287,387; 5,727,026; 5,930,299; 5,621,762; 5,381,449; 6,104,761; 6,147,984; 6,128,351; 6,128,350; 6,125,103; 6,097,252; 5,838,724; 5,835,536; 5,835,816; 5,838,724; 5,493,587; 5,384,547; 5,349,300; 5,302,914; 5,300,894; and 4,410,955.

What is needed, and is not believed to be found in the prior art, is a process whereby the AMR of a communication signal can be greatly reduced without causing significant degradation to the signal quality. Desirably, this process would allow the practical implementation of a polar modulator even for signals that have very high AMR.

### SUMMARY OF THE INVENTION

This invention, generally speaking, modifies pulse amplitude modulated signals to reduce the ratio of average power to minimum power. The signal is modified in such a manner that the signal quality remains acceptable. The signal quality is described in terms of the Power Spectral Density (PSD) and the Error Vector Magnitude (EVM).

Methods and apparatus are also disclosed for reducing signal degradation of a communications signal caused by reducing the average power to minimum power of the communications signal. According to an exemplary method, perturbation pulses to be combined with the communication signal are optimized by first defining an error function comprising the difference between a summation of perturbation pulse samples and a summation of reference pulse samples. The error function is minimized to determine optimized pulses, which when combined with the communications signal, do not substantially increase in-channel distortion of said communications signal. To avoid the generation of excessive out-of-band power, minimization is performed subject to a predetermined maximum allowable out-of-channel power condition.

The optimized pulses are inserted at times when the communications signal is determined to fall below a predetermined magnitude minimum, thereby reducing the average power to minimum power of the communications signal. Nonlinear filtering is performed in accordance with the optimized pulses to ensure that the optimized pulses, when combined with the communications signal, do not substantially contribute to in-channel distortion of the communications signal. The nonlinear filtering is also performed in a manner that ensures an out-of-channel power measure does not exceed a predetermined setting.

### BRIEF DESCRIPTION OF THE DRAWINGS

The present invention may be further understood from the following description in conjunction with the appended drawings. In the drawings:

FIG. 1 is a generic block diagram for generation of a PAM signal;

FIG. 2a is a block diagram of a PAM generator modified for AMR reduction;

FIG. 2b is a more detailed block diagram of an apparatus like that of FIG. 2a;

FIG. 3 shows the impulse response of a square-root raised-cosine pulse shaping filter with 22% excess bandwidth;

FIG. 4 shows an I-Q plot (vector diagram) of a portion of a QPSK signal with square-root raised-cosine pulse shaping;

FIG. 5 shows a section of the power of the pulse-shaped QPSK signal as a function of time;

FIG. 6 is a histogram showing the temporal location of signal magnitude minima, including only those minima that are more than 12 dB below the mean power;

FIG. 7 shows phase of the QPSK signal as a function of time;

FIG. 8 shows instantaneous frequency expressed as a multiple of the symbol rate for the signal of FIG. 7;

FIG. 9a illustrates a situation in which a mathematical model may be used to detect the occurrence of a low magnitude event;

FIG. 9b is a geometric illustration of the locally linear model for the complex signal envelope;

FIG. 9c illustrates calculation of t_min based on the locally linear model;

FIG. 10 shows a comparison of the original signal power and the power of the signal after addition of a single, complex-weighted pulse designed to keep the minimum power above −12 dB of average power;

FIG. 11 is an I-Q plot of a QPSK signal that has been modified to keep the instantaneous power greater than −12 dB relative to the RMS power;

FIG. 12 shows the instantaneous frequency of the modified signal, expressed as a multiple of the symbol rate;

FIG. 13 shows minimum power in the modified signal as a function of error in the time at which the corrective pulse is added (the magnitude and phase of the corrective pulse are held constant);

FIG. 14 shows estimated PSD of a conventional QPSK signal and the same signal after application of the exact hole-blowing method;

FIG. 15a is an I-Q plot of the modified signal after demodulation, showing that some distortion has been introduced into the signal (the measured RMS EVM is 6.3%);

FIG. 15b illustrates the results of non-linear filtering using a root-raised cosine pulse that is the same as the pulse-shaping filter;

FIG. 15c illustrates the results of non-linear filtering using a Hanning window for the correction pulse, with the time duration equal to ½ the symbol duration;

FIG. 16a is a block diagram illustrating symbol-rate hole-blowing;

FIG. 16b is a more detailed block diagram illustrating symbol-rate hole-blowing;

FIG. 16c is a block diagram illustrating the iteration of symbol-rate hole-blowing;

FIG. 16d is a block diagram illustrating the iteration of symbol-rate hole-blowing;

FIG. 16e is a block diagram illustrating the concatenation of one or more iterations of symbol-rate hole-blowing followed by one or more iterations of symbol-rate hole-blowing;

FIG. 17a is a block diagram of a portion of a radio transmitter in which polar domain nonlinear filtering is performed;

FIG. 17b is a more detailed block diagram of an apparatus like that of FIG. 17;

FIG. 18 is a waveform diagram showing the magnitude component of the polar coordinate signal and showing the difference of the phase component of the polar coordinate signal;

FIG. 19 is a diagram of the impulse response of a DZ3 pulse;

FIG. 20 is a waveform diagram showing results of nonlinear filtering of the magnitude component (showing the original magnitude component before polar domain nonlinear filtering, the magnitude component after the polar domain nonlinear filtering, the threshold, and the pulses added to the magnitude component);

FIG. 21 shows an example of an added pulse suitable for nonlinear filtering of the phase component;

FIG. 22 is a waveform diagram showing results of nonlinear filtering of the phase-difference component;

FIG. 23 illustrates an alternate way for nonlinear filtering of the phase component in a polar coordinate system;

FIG. 24 is a block diagram of a portion of a radio transmitter in which nonlinear filtering is performed first in the quadrature domain and then in the polar domain;

FIG. 25 is a PSD showing results of the nonlinear filtering of FIG. 34;

FIG. 26 is an I-Q plot for the UMTS signal constellation with one active data channel and a beta ratio of 7/15;

FIG. 27 is an I-Q plot for the UMTS signal constellation with two active data channels and a beta ratio of 7/15;

FIG. 28a illustrates the manner of finding the timings of low-magnitude events;

FIG. 28b compares probability density functions of low magnitude events using the exact algorithm and using the real-time approximation;

FIG. 29 is an I-Q plot illustrating a line-comparison method for vector quantization;

FIG. 30 illustrates a CORDIC-like algorithm for vector quantization;

FIG. 31 is an illustration of a known method of calculating the phase of the corrective pulse(s);

FIG. 32 shows Cumulative Distribution Functions (CDF) obtained with the present method and with known methods when the signal is pi/4 QPSK with raised cosine pulse-shaping and excess bandwidth of 22% (the desired minimum power is 9 dB below RMS);

FIG. 33 illustrates an example where the known symbol rate method works fairly well (the original signal envelope is shown, the modified envelope is shown, and the sample used to calculate the correction magnitude is indicated);

FIG. 34 illustrates an example where the known symbol rate method does not work well;

FIG. 35 illustrates an example where the known T/2 method does not work well;

FIG. 36 shows Cumulative Distribution Functions (CDF) obtained with the present method and the two known methods when the signal is a 3GPP uplink signal with one active DPDCH and amplitude ratio of 7/15 (the desired minimum power is 9 dB below RMS);

FIG. 37 is a simplified block diagram of a pulse optimizing signal conditioning apparatus, in accordance with an embodiment of the present invention;

FIG. 38 is a block diagram showing a digital transmitter that is configured to use the optimized pulse rₒₚₜ(t) generated by the pulse optimizer of the pulse optimizing signal conditioning apparatus in FIG. 37, and generate the corrected signal \dot{s}(t), in accordance with an embodiment of the present invention;

FIG. 39 is a graph showing PSD characteristics of an exemplary NLF producing a pulse having a predetermined ACLR; and

FIG. 40 is a flow chart highlighting salient steps involved in generating an optimized correction pulse rₒₚₜ(t), in accordance with an embodiment of the present invention.

### DETAILED DESCRIPTION OF THE PREFERRED EMBODIMENTS

A polar modulator can be viewed as a combination of a phase modulator and an amplitude modulator. The demands placed on the phase modulator and amplitude modulator are directly dependent on the bandwidth of the signal's phase and magnitude components, respectively. The magnitude and phase bandwidth, in turn, are dependent on the average-to-minimum magnitude ratio (AMR) of the signal. As will be shown later, a signal with large AMR can have very abrupt changes in phase, which means that the signal phase component has significant high frequency content. Furthermore, certain transistor technologies limit the AMR that can be achieved in a practical amplitude modulator. This limitation can lead to distortion of the transmitted signal if the required magnitude dynamic range exceeds that which can be generated by the transistor circuit. Thus minimization of signal AMR is highly desirable if the signal is to be transmitted with a polar modulator. One example of a polar modulator is described in U.S. patent application Ser. No. 10/045,199 entitled “Multi-mode communications transmitter,” filed on even date herewith and incorporated herein by reference.

The non-linear digital signal processing techniques described herein modify the magnitude and phase of a communication signal in order to ease the implementation of a polar modulator. Specifically, the magnitude of the modified signal is constrained to fall within a certain desired range of values. This constraint results in lower AMR compared to the original signal, which in turn reduces the magnitude and phase bandwidth. The cost of this reduction in bandwidth is lower signal quality. However, the reduction in signal quality is generally small, such that the final signal quality is more than adequate.

Signal quality requirements can typically be divided into in-band and out-of-band requirements. Specifications that deal with in-band signal quality generally ensure that an intended receiver will be able to extract the message sent by the transmitter, whether that message be voice, video, or data. Specifications that deal with out-of-band signal quality generally ensure that the transmitter does not interfere excessively with receivers other than the intended receivers.

The conventional in-band quality measure is the RMS error vector magnitude (EVM). A mathematically related measure is rho, which is the normalized cross-correlation coefficient between the transmitted signal and its ideal version. The EVM and rho relate to the ease with which an intended receiver can extract the message from the transmitted signal. As EVM increases above zero, or rho decreases below one, the transmitted signal is increasingly distorted relative to the ideal signal. This distortion increases the likelihood that the receiver will make errors while extracting the message.

The conventional out-of-band quality measure is the power spectral density (PSD) of the transmitted signal, or some measure derived therefrom such as ACLR, ACP, etc. Of particular interest in relation to PSD is the degree to which the transmitted signal interferes with other radio channels. In a wireless communications network, interference with other radio channels reduces the overall capacity of the network (e.g., the number of simultaneous users is reduced).

It should be clear that any means of reducing the average-to-minimum magnitude ratio (AMR) must create as little interference as possible (minimal degradation to out-of-band signal quality) while simultaneously maintaining the in-band measure of signal quality (i.e., EVM or rho) at an acceptable level. These considerations motivate the present invention, which reduces AMR while preserving out-of-band signal quality, which is of particular importance to operators of wireless communications networks.

In general, AMR reduction is performed by analyzing the signal to be transmitted, and adding carefully formed pulses into the signal in time intervals in which the signal magnitude is smaller than some threshold. The details of an exemplary embodiment, including the signal analysis and pulse formation, are described below, starting with a description of a class of signals for which the invention is useful.

Pulse-Amplitude Modulation (PAM)

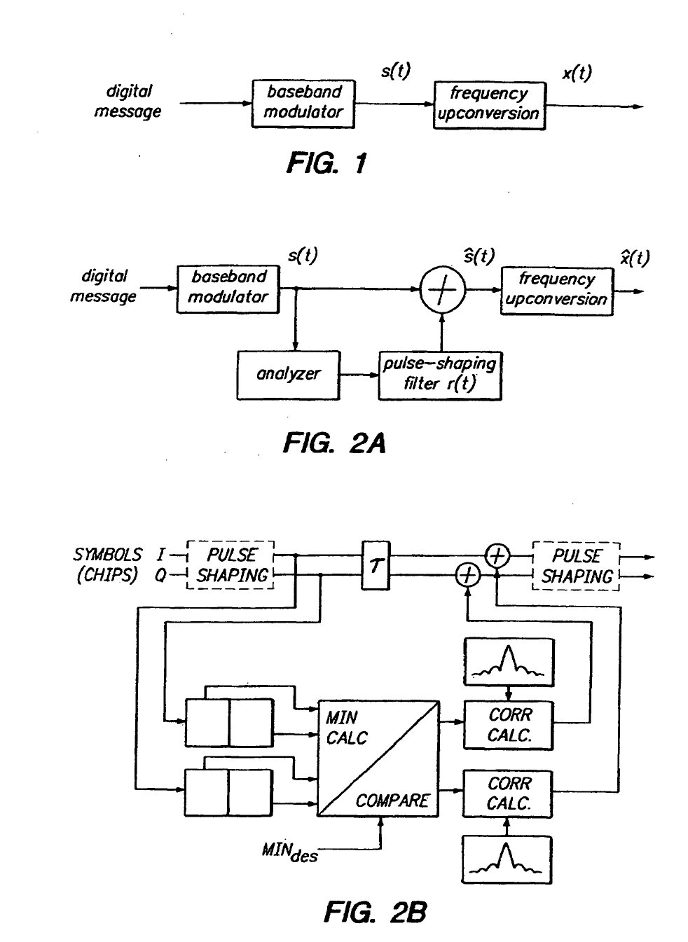

Many modern communication systems transmit digital messages using a scheme called pulse amplitude modulation (PAM). A PAM signal is merely a frequency-upconverted sum of amplitude-scaled, phase-shifted, and time-shifted versions of a single pulse. The amplitude-scaling and phase-shifting of the n^{th} time-shifted version of the pulse are determined by the n^{th} component of the digital message. In the field of communication systems, the broad class of PAM signals includes signals commonly referred to as PAM, QAM, and PSK, and many variants thereof. Mathematically, a PAM signal x(t) at time t can be described as follows, as will be recognized by those skilled in the art of communications theory. The description is given in two parts, namely the frequency-upconversion and amplification process, and the baseband modulation process, as shown in FIG. 1.

The frequency-upconversion and amplification process can be described mathematically as follows:
x(t)=Re{gs(t)e^{jw}^{_{c}}^{t)}}
where Re { } denotes the real part of its complex argument, ω_{c}=2πf_{c} defines the radio carrier frequency in radians per second and Hz, respectively, j is the imaginary square-root of negative unity, and g is the amplifier gain. This equation describes the frequency-upconversion process used to frequency-upconvert and amplify the complex baseband signal s(t), which is also the so-called I/Q (in-phase/quadrature) representation of the signal. The signal s(t), which is created by the baseband modulation process, is defined mathematically by

$$s ( t ) = {\sum }_{n} {a}_{n} p ( t - nT )$$

where p(t) is the pulse at time t and T is the symbol period (1/T is the symbol rate). For any time instant t at which s(t) is desired, the summation is taken over all values of n at which p(t−nT) is non-negligible. Also, aₙ is the symbol corresponding to the n^{th} component of the digital message. The symbol aₙ can be either real or complex, and can be obtained from the n^{th} component of the digital message by means of either a fixed mapping or a time-variant mapping. An example of a fixed mapping occurs for QPSK signals, in which the n^{th} component of the digital message is an integer dₙ in the set {0, 1, 2, 3}, and the mapping is given by aₙ=(jπdₙ/2). An example of a time-variant mapping occurs for π/4-shifted QPSK, which uses a modified QPSK mapping given by aₙ=(jπ(n+2 dₙ)/4); that is, the mapping depends on the time-index n, not only on the message value dₙ.

For the present invention, an important property of PAM signals is that the shape of the PSD (as a function of f) of a PAM signal is determined exclusively by the pulse p(t), under the assumption that the symbol sequence aₙ has the same second-order statistical properties as white noise. This property may be appreciated by considering the signal s(t) as the output of a filter having impulse response p(t) and being driven by a sequence of impulses with weights aₙ. That is, the PSD Sₓ(f) of x(t) can be shown to be equal to

$${S}_{x} ( f ) = \frac{{g}^{2} {σ}_{a}^{2}}{4 T} ( {\vert P ( f - {f}_{c} ) \vert}^{2} + {\vert P ( f + {f}_{c} ) \vert}^{2} )$$

where P(f) is the Fourier transform of the pulse p(t), and σₐ² is the mean-square value of the symbol sequence.

This important observation motivates the present method, because it suggests that adding extra copies of the pulse into s(t) does not alter the shape of the PSD. That is, nonlinear filtering performed in this manner can result in not just minor but in fact imperceptible changes in PSD. The adding of extra copies of the pulse into the signal can be used to increase the amplitude of x(t) as desired, for example when it falls below some threshold. Specifically, s(t) may be modified by adding additional pulses to it, to form new signals ŝ(t) and \hat{x}(t):

$$\hat{x} ( t ) = Re \{ g \hat{s} ( t ) {ⅇ}^{j {w}_{c} t} \}$$

$$where$$

$$\hat{s} ( t ) = {\sum }_{n} {a}_{n} p ( t - nT ) + {\sum }_{m} {b}_{m} p ( t - {t}_{m} )$$

and the perturbation instances tₘ occur at points in time when it is desired to perturb the signal (e.g., whenever the magnitude of s(t) falls below some threshold). The perturbation sequence bₘ represents the amplitude-scaling and phase-shifting to be applied to the pulse centered at time tₘ (e.g., chosen so as to increase the magnitude of s(t) in the vicinity of time tₘ). Like the first term in ŝ(t), the second term in ŝ(t) can be thought of as the output of a filter having impulse response p(t) and being driven by a sequence of impulses with weights bₘ. Thus, it is reasonable to expect that the PSDs of \hat{x}(t) and x(t) will have very similar shapes (as a function of frequency f).

With this theoretical underpinning, the present invention can be described in detail, in a slightly more general form than used above, as depicted in FIG. 2a. The invention takes the signal s(t) as its input. This signal passes into an analyzer, which determines appropriate perturbation instances tₘ, and outputs a perturbation sequence value bₘ at time instant tₘ. The perturbation sequence passes through a pulse-shaping filter with impulse response r(t), the output of which is added to s(t) to produce ŝ(t), which in turn is passed to any appropriate means for frequency upconversion and amplification to the desired power. The pulse-shaping filter r(t) can be identical to the original pulse p(t), as described above, or it can be different from p(t) (e.g., it may be a truncated version of p(t) to simplify implementation).

A more detailed block diagram is shown in FIG. 2b, illustrating a main signal path and a correction signal path for two signal channels, I and Q. Pulse-shaping may occur after pulse-shaping (sample-rate correction) or prior to pulse-shaping (symbol-rate correction). In the correction path, sequential values of I and Q are used to perform a signal minimum calculation and comparison with a desired minimum. If correction is required based on the comparison results, then for each channel the magnitude of the required correction is calculated. A pulse (which may be the same as that used for pulse-shaping) is scaled according to the required correction and added into the channel of the main path, which will have been delayed to allow time for the correction operations to be performed.

The method used to determine the timing, magnitude, and phase of the correction pulses is dependent on the modulation format. Factors to consider include:

1. The duration of low-magnitude events relative to the symbol period.

2. The timing distribution of low-magnitude events.

If the duration of all low-magnitude events are small relative to the symbol (or chip) duration, then each low-magnitude event can be corrected by the addition of a single complex-weighted pulse, which can be identical to that used in pulse-shaping. This approach would be effective with, e.g., M-ary PSK modulation. The appropriate hole-blowing method in this case is referred to as the “exact” hole-blowing method. The exact hole-blowing method is described below, as well as a practical real-time hardware implementation of the same. Other modulation formats may lead to low-magnitude events of relatively long duration. This would typically be the case with, e.g., QAM and multi-code CDMA modulation. In such cases multiple pulses may be added, or, alternatively, multiple iterations of the exact hole-blowing method be used. The usefulness of polar-domain hole-blowing has been demonstrated to perform “final clean-up” of a signal produced using one of the foregoing techniques, achieving even better EVM performance. Because magnitude information is available explicitly in the polar-domain representation, hole-blowing may be performed on a sample-by-sample basis, as compared to (typically) a symbol-by-symbol (or chip) basis in the case of the foregoing techniques.

The Exact Hole-Blowing Method

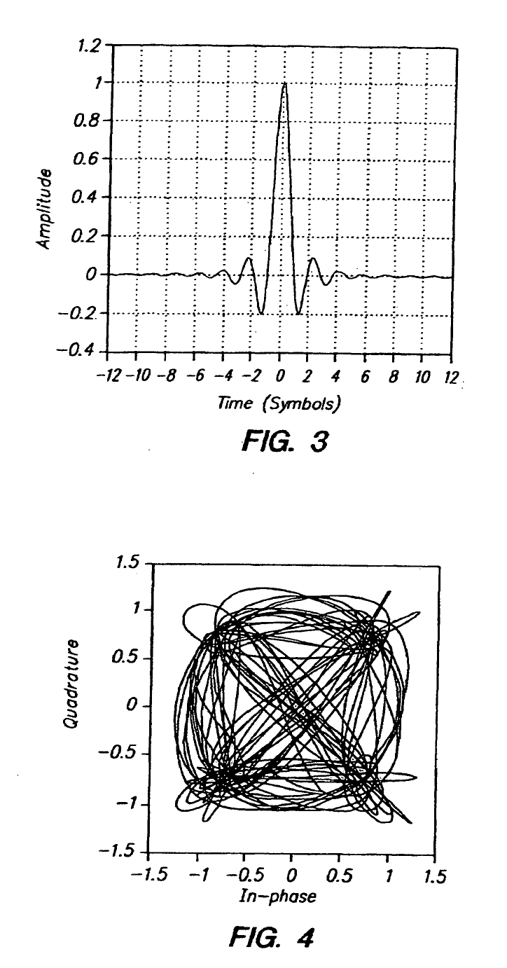

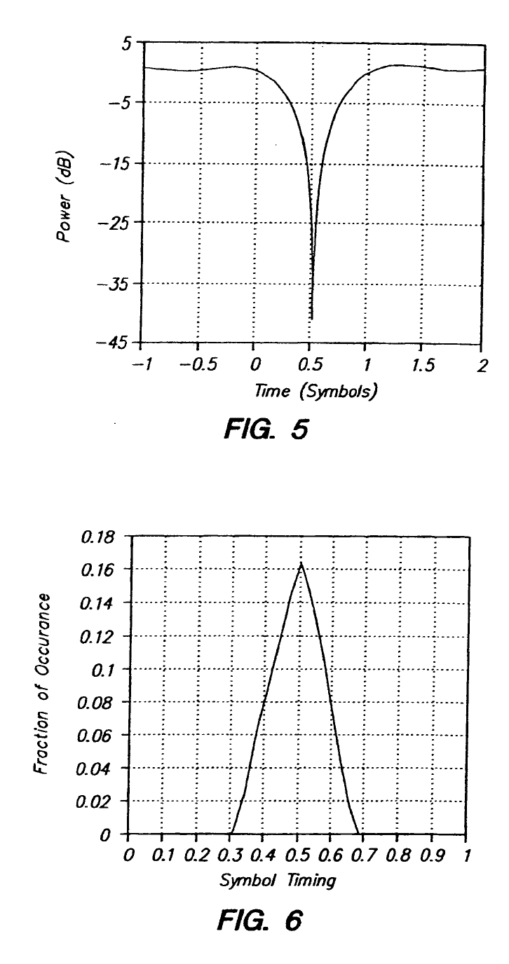

The detailed operation of the exact hole-blowing method is now demonstrated by example. A QPSK signal with square-root raised-cosine pulse shaping is used for this example. The pulse shaping filter has 22% excess bandwidth, and is shown in FIG. 3. A typical I/Q plot of this signal is presented in FIG. 4. Clearly the signal magnitude can become arbitrarily small. The signal power over a short period of time is shown in FIG. 5. The average power is normalized to unity (0 dB). This figure indicates that the AMR of this signal is at least 40 dB. In reality, the AMR for this QPSK signal is effectively infinite, since the signal power can become arbitrarily small. The timing of the minimum power is important, since the time instants at which to insert the correction pulses must be determined. One would expect that the power minima would approximately occur at t=nT/2, where n is an integer and T is the symbol period. This is supported by FIG. 5, which shows that the minimum power occurs very near T/2.

To further support this hypothesis, the distribution of the power minima timing was examined. For this purpose, a pulse-shaped QPSK waveform with random message was generated, and the timing at which the power minima occurred was determined. For this example, it is assumed that a low power event occurs if the instantaneous signal power was more than 12 dB below the mean signal power.

FIG. 6 shows a histogram of the timing of the QPSK signal magnitude minima. These results are based on 16384 independent identically distributed symbols. Note that the minima are indeed closely clustered around a symbol timing of T/2, as expected. This is an important result, since it limits the range over which the search for a signal minimum must be performed. (It should be noted that the histogram shown in FIG. 6 is only valid for this specific signal type (QPSK). Other signal types, such as high order QAM, may have different distributions, which must be taken into account in the search for local power-minima.)

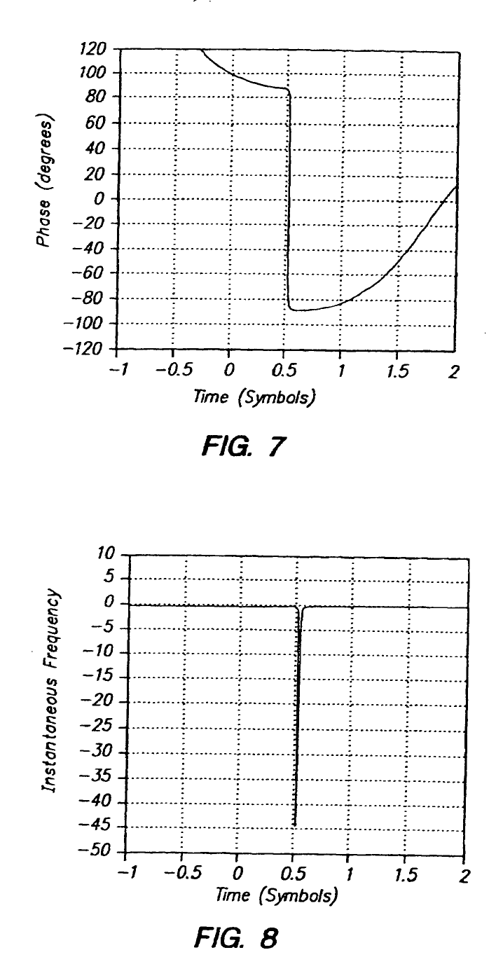

As stated previously, low-power events are associated with rapid changes in the signal phase. This correspondence is illustrated in FIG. 7, which shows the phase of the QPSK signal corresponding to the power profile shown in FIG. 5. It is clear that the phase changes rapidly near t=T/2, corresponding to the minimum power. This characteristic can be seen more explicitly in FIG. 8, which shows the instantaneous frequency, defined here for the sampled data waveform as

$${f}_{i} ( t ) = \frac{θ ( t + δ ) - θ ( t )}{2 π δ}$$

where θ(t) is the signal phase at time instant t and δ is the sampling period. FIG. 8 shows that the instantaneous frequency over this interval is up to 45 times the symbol rate. To put this in perspective, the chip rate for the UMTS 3GPP wideband CDMA standard is 3.84 MHz. If the symbol rate for the QPSK signal in our example was 3.84 MHz, the instantaneous frequency would exceed 45×3.84=172.8 MHz. Processing a signal with such high instantaneous frequency is not yet practical.

It is apparent that the bandwidth of the signal phase must be reduced in order to enable practical implementation of a polar modulator. The most obvious approach is to simply low-pass filter the phase (or equivalently the phase difference). However, any substantial filtering of the phase-difference will lead to unacceptably large non-linear distortion of the signal. This distortion in turn leads to a large increase in out-of-band signal energy, which is typically not acceptable. Instead the recognition is made that rapid changes in signal phase only occur when the signal magnitude is very small. Therefore if the signal magnitude can be kept above some minimum value, the bandwidth of the signal phase will be reduced. As should be evident from the discussion of PAM signal spectral properties, the signal can be modified by the addition of carefully selected pulses without any apparent effect on the signal bandwidth.

In order to avoid low-magnitude events, and consequently reduce the instantaneous frequency, a complex weighted version of the pulse-shaping filter is added to the signal. This complex weighted pulse is referred to as the correction pulse. The phase of the pulse is selected so that it combines coherently with the signal at the point of minimum magnitude. The magnitude of the correction pulse is equal to the difference between the desired minimum magnitude and the actual minimum magnitude of the signal.

Care must be taken in the calculation of the correction magnitude and phase in order to obtain the desired effect. Most importantly, it must be recognized that the minimum signal magnitude may not correspond to a sampling instant. Since the phase and magnitude are changing rapidly in the neighborhood of a local power minimum, choosing the correction phase based on a signal value that does not correspond to the signal minimum can lead to large phase and/or magnitude error. The likelihood of a large error increases as the minimum magnitude grows smaller. The likelihood of a large error can be lessened by using a very high sampling rate (i.e., a large number of samples per symbol), but this greatly, and unnecessarily, increases the computational load.

Instead, a so-called “locally linear model” is fitted to the signal in the temporal neighborhood of a local power minimum, and the minimum magnitude of the model is solved for mathematically. The locally linear model effectively interpolates the signal so that the magnitude can be calculated directly at any arbitrary time instant. In this way the calculation of the corrective pulses are not limited to the values present in the sampled data waveform. This allows for highly accurate calculation of the minimum magnitude and, of equal importance, the required correction phase.

Note that the complete pulse-shaped signal need not exist in order to calculate the correction magnitude and phase. The complex baseband signal need only be calculated at a small number of key sampling instants, allowing the non-linear filtering to operate on the raw symbols before a final pulse-shaping step. This expedient can be beneficial in real-time implementations.

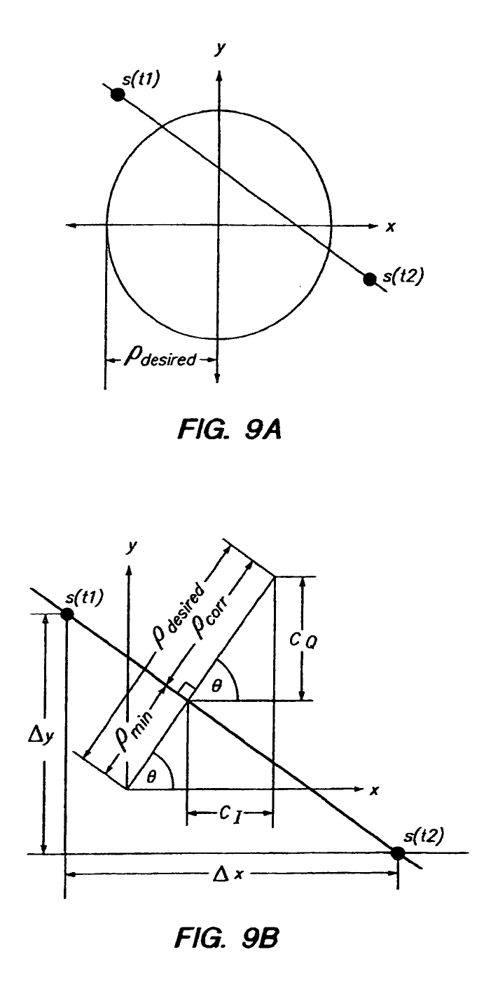

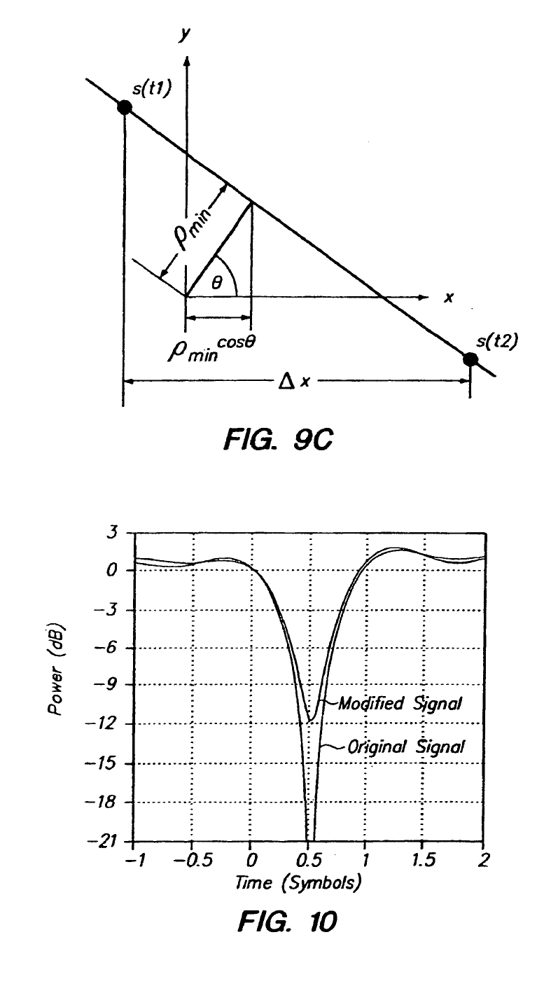

A signal may lie outside the exclusion region defined by the desired minimum at two points fairly near in time, yet pass through the exclusion region in between the two points, as illustrated in FIG. 9a. In order to find the true minimum value of the signal magnitude, and its corresponding phase, the following approach is preferably used. This approach employs a locally linear model for the complex baseband signal envelope, as illustrated in FIG. 9b. The model approximates the complex signal envelope by a straight line in I/Q space in the vicinity of the local power minimum. In many cases, if the desired minimum power is small, and the signal modulation is not too complicated (e.g., PSK), this model is quite accurate. Once this model has been fitted to the signal, the minimum magnitude of the locally linear model can be solved for directly.

In order to formulate the model, the complex signal must be known at no less than two distinct time instants. These time instants will preferably be close to the true minimum value of the signal, since the accuracy of the model is better in this case. These time instants need not correspond to sampling instants that are present in the sampled signal envelope.

Denote the complex signal at time t1 by s(t1). Denote the real and imaginary parts of s(t1) by x1 and y1, respectively. Similarly, denote the real and imaginary parts of s(t2) by x2 and y2, respectively. The signal at these time instants are given by:

$$s ( t 1 ) = {\sum }_{i} {a}_{i} p ( t 1 - iT )$$

$$s ( t 2 ) = {\sum }_{i} {a}_{i} p ( t 2 - iT )$$

where t2>t1, and t2−t1<<T. Then define
Δx=x2−x1
Δy=y2−y1

To the degree that the locally linear model is accurate, the complex signal at any instant in time t can be represented as
s(t)=s(t1)+cΔx+jcΔy
Re{s(t)}=x1+cΔx
Im{s(t)}=y1+cΔy
where c is a slope parameter.

In order to find the minimum magnitude of this linear model, a geometric approach based on FIG. 9b is used. The point of minimum magnitude corresponds to a point on the locally linear model that intersects a second line which passes through the origin and is orthogonal to the linear model, as illustrated in FIG. 9b. This orthogonal line can be described parametrically (using the parameter g) by the equations:
x=−gΔy
y=gΔx

The point of intersection is found by setting the x-axis and y-axis components of the linear model and the orthogonal line equal. This yields the following set of equations (two equations and two unknowns):
x1+cΔx=−gΔy
y1+cΔy=gΔx
Re-arranging these equations gives:

$$c = \frac{- ( g Δ y + x 1 )}{Δ x}$$

$$c = ( \frac{g Δ x - y 1}{Δ y} )$$

Setting these two expressions equal, and solving for g, gives:

$$g = \frac{( y 1 Δ x - x 1 Δ y )}{Δ {x}^{2} + Δ {y}^{2}}$$

The minimum magnitude of the linear model is then

$${ρ}_{min}^{2} = {( g Δ x )}^{2} + {( g Δ y )}^{2}$$

$$\begin{matrix}{ρ}_{min} = \vert g \vert \sqrt{Δ {x}^{2} + Δ {y}^{2}} \\ = \frac{\vert y 1 Δ x - x 1 Δ y \vert}{\sqrt{Δ {x}^{2} + Δ {y}^{2}}}\end{matrix}$$

The minimum magnitude as calculated from the locally linear model must be explicitly calculated in order to test for a low-magnitude event and to calculate the correction magnitude. The minimum magnitude is also used to calculate the magnitude of the correction pulse, which is given by:
ρ_{corr}=ρ_{desired}ρₘᵢₙ

The correction phase is equal to the phase of the signal at minimum magnitude, as determined from the locally linear model. If the corrections are being performed in the I/Q domain, there is no need to explicitly calculate the phase θ of the correction—only sin(θ) and cos(θ) need be calculated. Referring to FIG. 9b, it may be seen that:

$${ρ}_{min} cos θ = - g Δ y$$

$$\begin{matrix}cos θ = \frac{- g Δ y}{{ρ}_{min}} \\ = \frac{- Δ y ( y 1 Δ x - x 1 Δ y ) \sqrt{Δ {x}^{2} + Δ {y}^{2}}}{\vert y 1 Δ x - x 1 Δ y \vert ( Δ {x}^{2} + Δ {y}^{2} )} \\ = \frac{- Δ y sign ( y 1 Δ x - x 1 Δ y )}{\sqrt{Δ {x}^{2} + Δ {y}^{2}}}\end{matrix}$$

where c/|c|=sign(c) for any scalar c. Similarly:

$$sin θ = \frac{Δ x sign ( y 1 Δ x - x 1 Δ y )}{\sqrt{Δ {x}^{2} + Δ {y}^{2}}}$$

In rectangular coordinates, the in-phase and quadrature correction factors will respectively have the form:
c_{I}=(ρ_{desired}−ρₘᵢₙ)cos θ
c_{Q}=(ρ_{desired}−ρₘᵢₙ)sin θ
Thus, it is seen that cos θ and sin θ are sufficient in order to calculate the correction factors, and the independent determination of signal phase θ is not necessary. The modified signal in rectangular coordinates is given by:
ŝ_{I}(t)=s_{I}(t)+c_{I}p(t−tₘᵢₙ)
ŝ_{Q}(t)=s_{Q}(t)+c_{Q}p(t−tₘᵢₙ)
where t_min is the approximate time at which the local minimum occurs, and the pulse is assumed (without loss of generality) to be normalized such that p(0)=1.

In some applications it may be desirable to obtain a precise estimate of the time t_min corresponding to the minimum signal power. Here, “precise” is used to mean an estimate that is not limited by the sample rate, and may have an arbitrary degree of accuracy. For example, given t_min, correction pulses may be added to the signal based on an interpolated or highly oversampled prototype pulse p(t). For this purpose, any of the three following procedures that exploit the locally linear model can be used. The first two approaches are based on geometric arguments. The third approach is based on direct minimization of the signal magnitude.

Linear interpolation is typically employed to estimate a signal value at some arbitrary time t when the signal is only known at two or more discrete time indices. That is, linear interpolation is used to find s(t) given t. However, linear interpolation can also be used to find t given s(t). This property may be exploited as follows, in accordance with the illustration of FIG. 9c. The linear model is

$$s ( t ) = s ( t 1 ) + c ( Δ x + j Δ y )$$

$$where$$

$$c = \frac{t - t 1}{t 2 - t 1}$$

For the real part of the signal,

$$x = {x}_{1} + \frac{t - {t}_{1}}{{t}_{2} - {t}_{1}} ( {x}_{{2}^{-}} {x}_{1} )$$

Solving this expression for t,

$$t = {t}_{1} + \frac{x - {x}_{1}}{{x}_{2} - {x}_{1}} ( {t}_{2} - {t}_{1} )$$

The calculation of t_min depends on the calculation of x_min, the real part of the signal at the local minimum magnitude. As described previously, the minimum magnitude of the signal is ρₘᵢₙ; the real part of the signal at minimum magnitude is ρₘᵢₙ cos θ. Therefore

$${t}_{min} = {t}_{1} + ( \frac{{ρ}_{min} cos θ - {x}_{1}}{{x}_{2} - {x}_{1}} ) ( {t}_{2} - {t}_{1} )$$

Based on similar arguments for the imaginary part of the signal, alternatively

$${t}_{min} = {t}_{1} + ( \frac{{ρ}_{min} sin θ - {y}_{1}}{{y}_{2} - {y}_{1}} ) ( {t}_{2} - {t}_{1} )$$

The two expressions described above only depend on the real part or imaginary part of the signal. In a finite precision implementation, this may be a drawback if the change in x or y is small. Therefore it may be better in practice to use an expression which is dependent on both the real and imaginary parts of the signal. Such an expression can be derived by direct minimization of the signal magnitude using standard optimization procedures. Using the linear model, the signal magnitude is
|s(t)|²=(x₁+cΔx)²+(y₁+cΔy)²
Taking the derivative with respect to c,

$$\frac{\partial }{\partial x} {\vert s ( t ) \vert}^{2} = 2 ( {x}_{1} + c {Δ}_{x} ) {Δ}_{x} + 2 ( y 1 + c {Δ}_{y} ) {Δ}_{y}$$

Setting the derivative equal to zero and solving for c,

$${c}_{min} = \frac{- ( {x}_{1} {Δ}_{x} + {y}_{1} {Δ}_{y} )}{{Δ}_{x}^{2} + {Δ}_{y}^{2}}$$

Thus the final expression for t_min is

$${t}_{min} = {t}_{1} + ( \frac{- ( {x}_{1} {Δ}_{x} + {y}_{1} {Δ}_{y} )}{{Δ}_{x}^{2} + {Δ}_{y}^{2}} ) ( {t}_{2} - {t}_{1} )$$

The “exact” hole-blowing algorithm can thus be summarized as follows:
1. Determine the approximate timing t=t1 of a potential low-magnitude event in the signal.
2. In the temporal neighborhood of a potential low-magnitude event, calculate the pulse-shaped signal s(t) for at least two distinct time instants t1 and t2>t1, where t2−t2>>T. In the case of symbol-rate hole-blowing, the signal s(t) is calculated based on the later-to-be-applied bandlimiting pulse and some number of symbols in the vicinity of t1 and some number of symbols in the vicinity of t2. In the case of sample-rate (i.e., oversampled) hole-blowing, pulseshaping will have already been performed, such that s(t1) and s(t2) may be chosen to correspond with adjacent samples.
3. Calculate the minimum magnitude ρₘᵢₙ using the “locally-linear model”, detailed above, and tₘᵢₙ, the time of ρₘᵢₙ.
4. Compare the calculated minimum magnitude to the desired minimum magnitude.
5. If the calculated minimum magnitude is less than the desired minimum magnitude, calculate the in-phase and quadrature correction weights c_{I} and c_{Q}, respectively, as detailed above.
6. Weight two copies of the pulse-shaping filter by the in-phase and quadrature correction values, respectively.
7. Add these weighted copies of the pulse-shaping filter to the in-phase and quadrature components of the signal, referenced to tₘᵢₙ.
8. Translate the modified in-phase and quadrature components to magnitude and phase, forming the signals to be processed by a polar modulator.

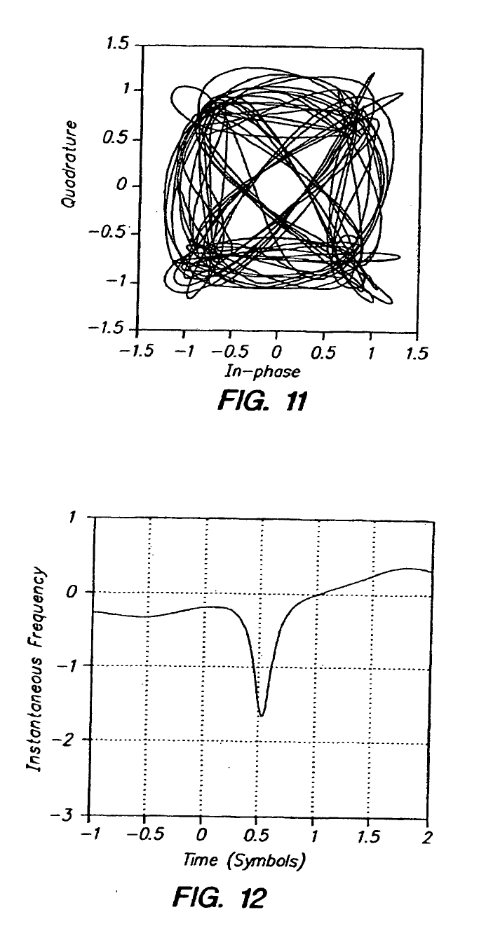

The effectiveness of the exact hole-blowing method described above is evident in FIG. 10, comparing the instantaneous power of the original QPSK signal to the signal after processing with the exact hole-blowing method. The threshold for desired minimum power in this example was selected to be 12 dB below RMS power. It can be seen that the exact hole-blowing method is highly effective in keeping the signal power above the desired minimum value. The I-Q plot of the QPSK signal after hole-blowing is shown in FIG. 11. It can be seen that all traces have been pushed outside the desired limit. A “hole” appears in I-Q plot where none was evident before.

The instantaneous frequency of the modified signal is shown in FIG. 12. By comparison with FIG. 8, it can be seen that the instantaneous frequency has been reduced from approximately 45× the symbol rate to approximately 1.5× the symbol rate. Clearly the method has greatly reduced the instantaneous frequency.

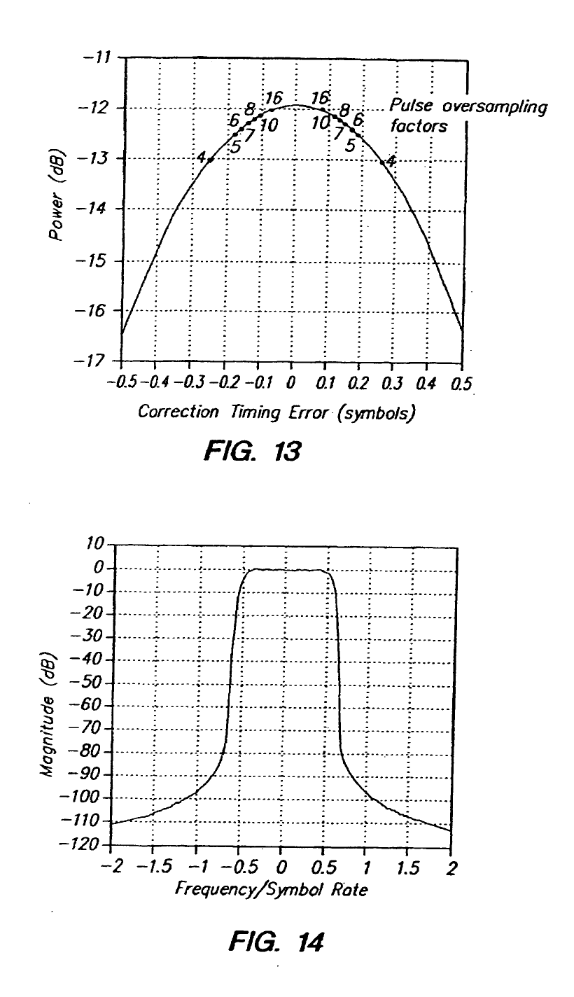

It should be noted that the exact hole-blowing method described here is highly tolerant of timing error, but relatively intolerant of magnitude and phase error (or equivalent errors in the correction factors c_{I} and c_{Q}). Timing error refers to the time at which the corrective pulse is added to the original signal. This tolerance to timing error is due to the fact that the pulse shaping filter generally will have a fairly broad magnitude peak relative to the duration of the low-magnitude event. The effect of this sort of timing error is shown in FIG. 13, where a timing error of up to one-fourth of a symbol period degrades the AMR by only 1 dB.

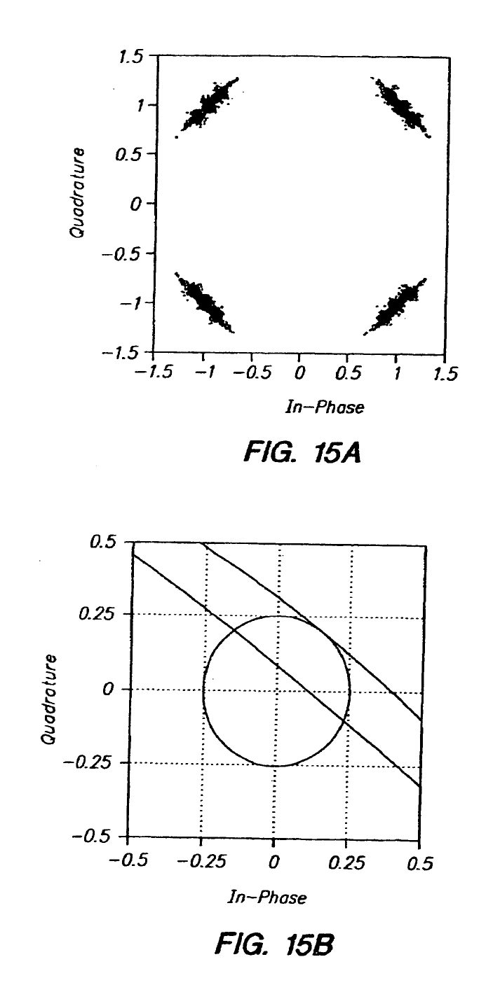

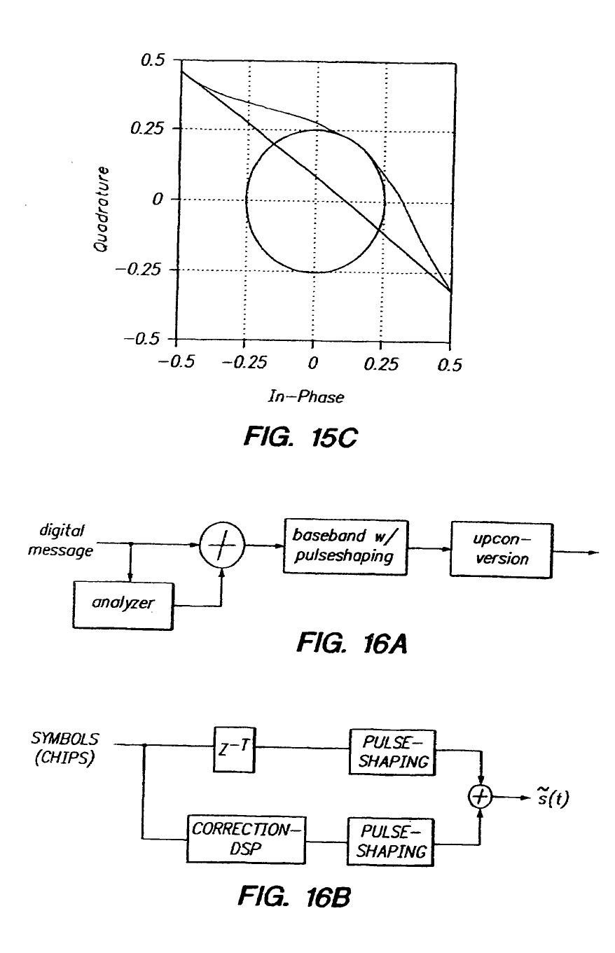

Having shown that the exact hole-blowing method is effective in removing low-magnitude events, the effect on in-band and out-of-band signal quality will now be described. The PSDs of the QPSK signal before and after hole-blowing are indistinguishable in the frequency domain as shown in FIG. 14. The effect on EVM is illustrated in FIG. 15a, showing an I-Q plot of the modified signal after matched-filtering and baud-synchronous sampling. The result shows the message that a receiver would obtain upon demodulation of the modified signal. It can be seen that distortion has been introduced to the signal, in that not all samples fall exactly on one of the four QPSK constellation points. The RMS EVM can be defined as

$${σ}_{even} = \frac{\sqrt{\frac{1}{N} {\sum }_{k = 0}^{N - 1} {\vert {a}_{k} - {\hat{a}}_{k} \vert}^{2}}}{\sqrt{\frac{1}{N} {\sum }_{k = 0}^{N - 1} {\vert {a}_{k} \vert}^{2}}}$$

where aₖ and âₖ are, respectively, the ideal and actual PAM symbols. For the particular example illustrated in FIG. 14, the RMS EVM was calculated using N=16384 symbols and found to be 6.3%. Similarly, the peak EVM is defined as follows:

$$p {k}_{evm} = max \frac{\vert {a}_{k} - {\hat{a}}_{k} \vert}{\sqrt{\frac{1}{N} {\sum }_{k = 0}^{N - 1} {\vert {a}_{k} \vert}^{2}}}$$

In this example, the peak EVM is found to be about 38%. If the signal is allowed to have greater magnitude dynamic range, the RMS EVM will be lower. Recall, however, that increasing the allowed magnitude dynamic range also increases the bandwidth and peak value of the instantaneous frequency. Accordingly, a tradeoff can be made between the desired signal quality (EVM) and the instantaneous frequency requirements placed on a practical polar modulator.

To assure an imperceptible effect on the signal PSD (see FIG. 14), the choice of the correction pulse shape should substantially match the signal band limiting pulse shape. When the pulse oversampling rate is four or more (samples per symbol time), the preceeding algorithm can be simplified. Specifically, the calculation of tₘᵢₙ can be eliminated, and the correction pulse is inserted time-aligned with the existing signal sample s(t1). As shown in FIG. 13, the maximum error in minimum magnitude is 1 dB for 4× oversampling, and decreases to 0.2 dB for 8× oversampling.

The difference in practice between an approach in which hole-blowing is performed taking account of tₘᵢₙ and an approach in which the calculation of tₘᵢₙ can be eliminated is illustrated in the examples of FIGS. 15b and 15c, respectively. In the example of FIG. 15b, hole-blowing was performed using a root-raised cosine pulse that was the same as the pulse-shaping pulse. In the example of FIG. 15c, hole-blowing was performed using a Hanning window for the correction pulse, with a time duration equal to ½ the symbol duration. As may be seen, in FIG. 15c, the original signal trajectory is changed as little as possible is order to skirt the region of the hole. In many instances (if not most), however, the calculation of tₘᵢₙ can be eliminated (as in FIG. 15b).

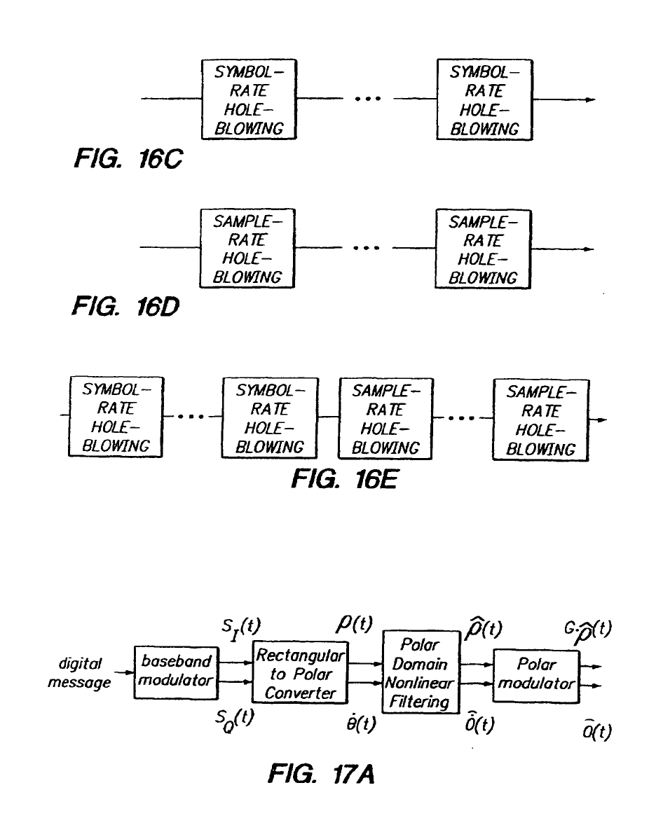

FIG. 16a shows an arrangement for symbol-rate hole-blowing. A digital message is applied to a main path in which pulse-shaping and upconversion are performed. An auxiliary path includes an analyzer block that produces a correction signal. An adder is provided in the main path to sum together the main signal and the correction signal produced by the analyzer.

Referring to FIG. 16b, a particularly advantageous embodiment for performing symbol-rate hole-blowing is shown. Two signal paths are provided, a main path and an auxiliary path. Outputs of the main signal path and the auxiliary signal path are summed to form the final output signal.

The main signal path receives symbols (or chips) and performs pulse-shaping on those symbols (or chips), and is largely conventional. However, the main signal path includes a delay element used to achieve synchronization between the main signal path and the auxiliary signal path.

In the auxiliary path, the symbols (or chips) are applied to a correction DSP (which may be realized in hardware, firmware or software). The correction DSP performs hole-blowing in accordance with the exact method outlined above and as a result outputs an auxiliary stream of symbols (or chips). These symbols (or chips) will occur at the same rate as the main stream of symbols (or chips) but will be small in magnitude in comparison, and will in fact be zero except when the signal of the main path enters or is near the hole. The relative timing of the main and auxiliary paths may be offset by T/2 such that the small-valued symbols of the auxiliary path occur at half-symbol timings of the main signal path.

In an exemplary embodiment, the correction DSP calculates the signal minimum with respect to every successive pair of symbols (or chips), by calculating what the signal value would be corresponding to the respective symbols (or chips) and applying the locally linear model. In calculating what the signal value would be corresponding to a symbol (or chip), the same pulse as in the main signal path and is applied to that symbol (or chip) and some number of previous and succeeding symbols (or chips). This use of the pulse to calculate what the value of the signal at a particular time will be following pulse-shaping is distinct from the usual pulse-shaping itself.

After the correction symbols (or chips) of the auxiliary signal path have been determined, they are pulse-shaped in like manner as those of the main signal path. The pulse-shaped output signals of the main and auxiliary paths are then combined to form the final output signal.

Since the duration of p(t) is finite (L), the signal can be evaluated ahead of time for the correlation between low-magnitude events and the input symbol stream (L^{M} cases). The analyzer can then operate solely on the {aᵢ} to determine the cᵢ and tᵢ. (The correction symbols cᵢ are very small, and have negligible effect on the message stream.) In this variant of symbol-rate hole-blowing, the calculated symbols bₘ are added to the original message stream, and the entire new stream is bandlimited once through the filter.

Rather than pulse shaping the correction symbols flowing through the auxiliary path in like manner as those flowing through the main signal path (as described in the exemplary embodiment above), in an alternative embodiment, methods and apparatus are provided to optimize the pulses of the symbols in the auxiliary signal path prior to being combined with the pulse-shaped signals of the main signal path. As explained in more detail below, the apparatus and methods according to this aspect of the invention are operable to design an optimized non-linear-filtered correction pulse rₒₚₜ(t) having an optimized EVM subject to a predetermined adjacent channel leakage ratio (ACLR).

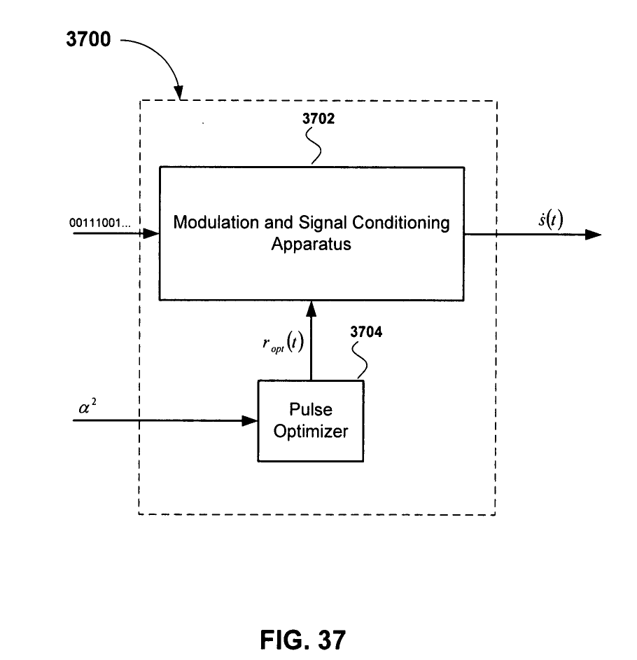

FIG. 37 is a simplified block diagram of a pulse optimizing signal conditioning apparatus 3700, in accordance with an embodiment of the present invention. The pulse optimizing signal conditioning apparatus 3700 comprises a modulation and signal conditioning apparatus 3702 and a pulse optimizer 3704. The modulation and signal conditioning apparatus 3702 is configured to receive a digital message and generate a corrected signal \dot{s}(t). The pulse optimizer 3704 is configured to receive energy parameters α² characterizing a predetermined adjacent channel leakage ratio (ACLR) and compute an optimized pulse rₒₚₜ(t), which is used by a nonlinear filter (NLF) of the signal and conditioning apparatus 3702 to generate the corrected signal \dot{s}(t).

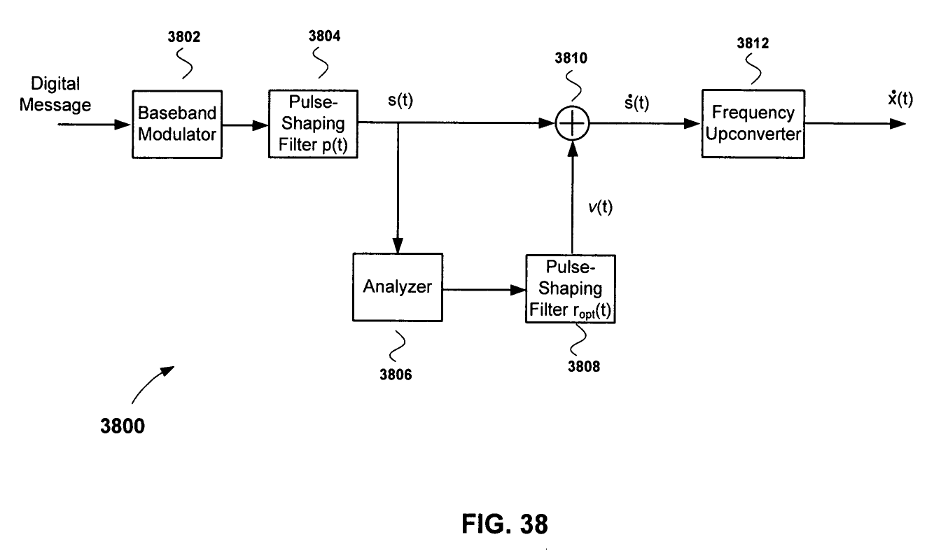

FIG. 38 is a block diagram showing a digital transmitter 3800 that is configured to use the optimized pulse rₒₚₜ(t) generated by the pulse optimizer 3704 of the pulse optimizing signal conditioning apparatus 3700 in FIG. 37, and generate the corrected signal \dot{s}(t), in accordance with an embodiment of the present invention. The digital transmitter 3800 comprises a main signal path having a baseband modulator 3802 coupled to a first pulse shaping filter 3804 and an auxiliary path having an analyzer 3806 coupled to a second pulse shaping filter 3708.

The baseband modulator 3802 is configured to receive a digital message and generate a stream of digital symbols in the form of a series of weighted impulses. The first pulse shaping filter 3804, which has an impulse response p(t), is configured to receive the series of weighted impulses and generate an uncorrected pulse-shaped signal:

$$s ( t ) = {\sum }_{n} {a}_{n} p ( t - nT )$$

where T is the symbol period.

The uncorrected pulse-shaped signal s(t) is coupled to an input of the analyzer 3806, which is operable to generate a perturbation sequence comprising a stream of correction impulses having weights cₘ for times when the uncorrected pulse-shaped signal s(t) has magnitudes that fall below a predetermined magnitude threshold. The correction impulses are then pulse-shaped by the second pulse-shaping filter 3808 to form a correction signal (i.e., perturbation signal), which can be expressed as:

$$v ( t ) = {\sum }_{m} {c}_{m} {r}_{opt} ( t - {t}_{m} )$$

where rₒₚₜ(t) is the impulse response of the second pulse shaping filter 3808 and tₘ represents perturbation times when it is desired to perturb the original pulse-shaped signal s(t). According to the exemplary embodiments described below, the correction pulses are designed for half-symbol timing (t=nT+T/2), where n is an integer. However, those of ordinary skill in the art will readily appreciate and understand that the structure and methods employed to generate the optimized correction pulses rₒₚₜ(t) can be performed for insertion of the correction pulses rₒₚₜ(t) at other time instants.

The signals processed in the main and auxiliary paths are combined by a combiner 3810, thereby forming the corrected signal (or “perturbed” signal) \dot{s}(t), which may be expressed as follows:

$$\begin{matrix}\dot{s} ( t ) = s ( t ) + v ( t ) \\ = {\sum }_{n} {a}_{n} p ( t - nT ) + {\sum }_{m} {c}_{m} {r}_{opt} ( t - {t}_{m} ) \\ = {\sum }_{n} {a}_{n} p ( t - nT ) + {\sum }_{n} {c}_{n} {r}_{opt} ( t - nT - T / 2 )\end{matrix}$$

Finally, the corrected signal \dot{s}(t) is coupled to a frequency upconverter 3812, which upconverts the corrected signal up to an RF signal \dot{x}(t), which can be transmitted over a wireless link to a wireless receiver.

Combining the correction pulses r(t) with the main signal data inevitably introduces some distortion in the resulting signal \dot{s}(t). The methods used to form the corrected signal \dot{s}(t), particularly with regard to generating the optimized pulse rₒₚₜ(t) by the pulse optimizer 3704 in FIG. 37 are now described in more detail.

Optimization of the correction pulses r(t) involves reducing the EVM contributed by the correction pulses, while satisfying a predetermined ACLR. The RMS EVM of a signal is defined as the square root of the ratio of the mean error vector power to the mean reference signal power. It is measured by comparing samples of \dot{s}(t) at the output of the matched filter of the receiver. RMS EVM can be expressed in various ways. For example, it can be expressed in accordance with the 3GPP UMTS specification as follows:

$$RMS EVM = \frac{\sqrt{\frac{1}{2560} {\sum }_{n = 1}^{2560} {\vert {z}_{n , measure} - {z}_{n , ideal} \vert}^{2}}}{\sqrt{\frac{1}{2560} {\sum }_{n = 1}^{2560} \vert {z}_{n , ideal}^{2} \vert}}$$

$$where$$

$${z}_{n , measured} = {z}_{n , ideal} + {\sum }_{m = - ∞}^{∞} {I}_{n , m}$$

and z_{n,measured} is the ideal signal output at time n and I_{n,m} is the signal distortion introduced by the NLF (i.e., hole blowing) process. The measurement interval is one power control group and the number 2560 is derived from the number of symbols per power control group. For simplicity, it has been assumed that the best sampling instance for detection is some integer multiple of the symbol period T.

By minimizing the signal power of the inserted pulse r(t) used for NLF at the sampled instance, the RMS EVM can be greatly reduced. However, while minimizing the signal power has the effect of reducing the RMS EVM, the ACLR can become unacceptable if the minimization does not properly take into account energy leakage into channels adjacent the desired channel. Accordingly, in addition to minimizing the RMS EVM, optimization of the design pulse should, in most cases, require that minimization of the RMS EVM be performed in a manner that satisfies a predetermined ACLR.

ACLR is defined as the ratio of the power measured in an adjacent channel to the transmitted power. It is measured at the matched filter output of the receiver but before the received signal is sampled. ACLR can be expressed in various ways. For example, it can be expressed according to the 3GPP UMTS specification as:

$$ACLR ( dB ) = 10 * log 10 ( \frac{\int {q}_{1}^{2} ( t ) ⅆ t}{\int {q}_{2}^{2} ( t ) ⅆ t} )$$

where q₁(t) represents the desired signal output of the desired channel and q₂(t) represents the signal leakage to the adjacent channel.

Given the expressions for RMS EVM and ACLR above, an algorithm is now described which designs an optimized correction pulse rₒₚₜ(t). First, a reference (or “ideal”) pulse is selected for NLF. The selected reference pulse should have the effect of introducing as little in-band distortion into the corrected signal \dot{s}(t) as possible. According to one aspect of the invention, the selected reference pulse comprises an impulse with infinite bandwidth having energy that is evenly distributed in frequency. Since most of the in-band signal energy occupies only a small portion of the entire frequency band, most of the pulse energy is allocated outside the transmission band. Selecting an impulse for the reference pulse is beneficial in that it represents the least amount of energy required to push the signal away from the origin for a given threshold at a particular instance in time.

After the reference pulse is selected and defined, a design (or “correction”) pulse is determined that best approximates the reference pulse at the sampled output of the matched filter of the receiver. Using an impulse function for the reference pulse (for the reasons set forth in the previous paragraph), the design pulse can be determined by minimizing the sum-of-square error (SSE) of the sampled output:

$$\begin{matrix}SSE = {\sum }_{k} {\vert r ( t - T / 2 ) ⊗ p ( t ) { {\vert}_{t = kT} - δ ( t - T / 2 ) p ( t ) \vert}_{kT} \vert}^{2} \\ = {\sum }_{k} {\vert r ( t - T / 2 ) ⊗ p ( t ) {\vert}_{t = kT} - b ( kT ) \vert}^{2}\end{matrix}$$

where δ represents the impulse function, [symbol] denotes convolution, and b(t)=p(t−T/2). The SSE in the above equation is a summation of samples, which can be equivalently expressed using matrix representation as follows:
SSE(τ)=∥A′(τ)r−b₀(τ)∥²
where τ represents the sample delay and r is the design pulse. The SSE can then be minimized with respect to the sample delay τ and the design pulse r(t), thereby yielding the minimum SSE at the sampled output of the receiver's matched filter. This minimization process can be expressed as:

$${min}_{\underline{r}} {min}_{τ} SSE ( τ )$$

Once the correction pulse r(t) is designed for minimum EVM, an optimization algorithm is employed to balance the in-band and out-of-band energy to arrive at an optimized pulse rₒₚₜ(t). As discussed above, out-of band energy is characterized by ACLR. The maximum acceptable ACLR is dependent on the communications standard being used and/or on a particular design requirement.

Since the signal strength of the correction signal v(t) is much smaller than the original, uncorrected signal s(t) in the main signal path, the original, uncorrected signal s(t) dominates the ACLR performance of the corrected signal \dot{s}(t). For example, assume that the design objective is −60 dB ACLR of the corrected signal \dot{s}(t). The pulse-shaping filter for the main signal path (e.g., the first pulse-shaping filter 3704 in FIG. 37) would then have to be designed to have an ACLR less than 60 dB, while the pulse-shaping filter for NLF (e.g., the second pulse shaping filter 3708 in FIG. 37) for the corrective signal v(t) could be designed to have an ACLR as high as −40 dB.

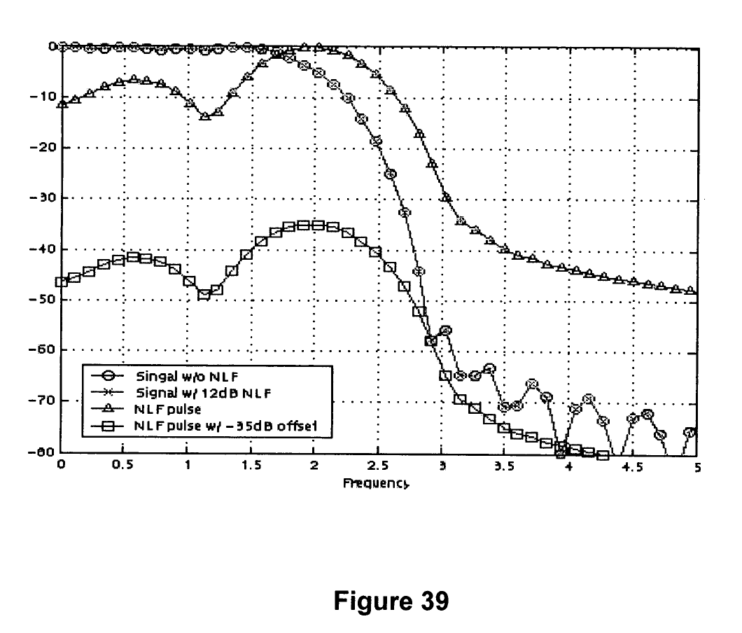

PSD characteristics of the exemplary design described in the previous paragraph are shown in FIG. 39. The curve with the squares represents the PSD of the reverse link UMTS signal without NLF. The curve with the “x's” represents the PSD of the same signal but with 12 dB NLF. As can be observed from the plot, the PSDs of the two signals substantially overlap and no obvious trace of the signal used for NLF can be observed. The PSD of the pulse used for NLF is plotted as the line with triangles and the pulse itself has an ACLR of approximately −40 dB. However, the signal energy used for NLF is so small that it is barely observable when combined with the uncorrected signal. This characteristic is highlighted in the curve with the line with squares, where it can be seen that the curve is a pushed-down version of the line with triangles. The pushed-down version of the pulse used for NLF is below the PSD of the uncorrected signal, and therefore, has little effect on the overall ACLR measurement.

With the above considerations in mind, a NLF pulse having a predetermined ACLR (e.g., −40 dB) can be designed. It can be shown that for zero-mean uncorrelated symbols, the ACLR is a function of only p(.) and the NLF pulse r(.) The in-channel component can be expressed as:
in-channel component=∫|r(t) [symbol] p(−t)|²dt
The off-channel is obtained similarly but using a frequency-shifted matched filter:
off-channel component (i)=∫|r(t) [symbol] p(−t)e^{k2πf}^{ᵢ}^{t}|²dt
where fᵢ is the frequency offset of the i'th adjacent channel.

Completing the design of the NLF having the prescribed ACLR requires the minimization of ACLRs at multiple channels. This can be accomplished by minimizing the weighted sum of ACLRs. For channels having more stringent ACLR requirements, a correspondingly larger weighted sum can be applied, as follows:

$${ACLR}_{tot} = {\sum }_{i} {w}_{i} {ACLR}_{i} = {\sum }_{i} {w}_{i} \frac{off channel component ( i )}{on channel component}$$

where wᵢ is the ACLR weighting factor for channel i. ACLRₜₒₜ can also be expressed in matrix form as:

$${ACLR}_{tot} = \frac{{‖ {B}_{\underline{\_}} \underline{r} ‖}^{2}}{{‖ A {r}_{\underline{\_}} ‖}^{2}}$$

Combining the two constraints discussed above, i.e., minimizing SSE while maintaining a predetermined ACLR requirement, a design filter (i.e. NLF) for producing an optimized correction pulse rₒₚₜ(t) can be made by solving the following problem:

$${min}_{\underline{r}} {min}_{τ} SSE ( τ ) \qquad subject to ( s . t . ) \qquad {ACLR}_{tot} = {α}^{2}$$

The problem can be solved by minimizing SSE:

$${min}_{\underline{r}} SSE ( τ ) s . t . {ACLR}_{tot} = {α}^{2}$$

for each τ and then selecting the τ for which the minimization is smallest. This minimization can be expressed using matrix notation as follows:

$${min}_{\underline{r}} {‖ {A}^{′} \underline{r} - {\underline{b}}_{0} ‖}^{2} s . t . \frac{{‖ {B}_{\underline{\_}} \underline{r} ‖}^{2}}{{‖ A \underline{r} ‖}^{2}} = {α}^{2}$$

The minimization problem can be further simplified to a least squares minimization with a quadratic inequality constraint (LSQI) problem by dropping the denominator ∥Ar∥ˆ2, which is just a scaling factor. The solution to the LSQI problem

$${min}_{\underline{r}} {‖ {A}^{′} \underline{r} - {\underline{b}}_{0} ‖}^{2} s . t . ‖ {B}_{\underline{\_}} \underline{r} ‖ = {α}^{2}$$

can then be found by consulting standard matrix computation textbooks.

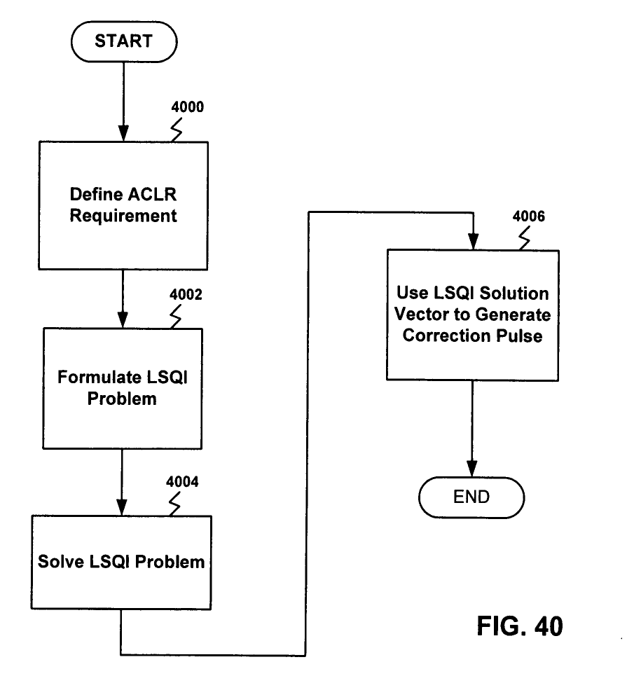

FIG. 40 is a flow chart summarizing the pulse optimization algorithm described above. In a first step 4000, an ACLR requirement is determined, from which a predetermined ACLR is set to satisfy an ACLR specification (e.g., as directed by a wireless communication standard or as required by a particular design application). At step 4002, a minimization problem (e.g., an LSQI problem) is formulated subject to the predetermined ACLR. Next, at step 4004 the minimization problem is presented to a minimization problem solver, which solves the minimization problem. The minimization problem solver can be implemented in various ways, including but not limited to hardware, firmware, software, and/or as an external dedicated apparatus. Finally, at step 4006 results generated by the minimization problem solver are used to generate the desired design (i.e., optimized) pulse rₒₚₜ(t).

Iterative Methods

The foregoing description has focused on symbol-rate and sample-rate hole-blowing techniques. Although the term “exact” has been used to refer to these techniques, some inaccuracy and imprecision is inevitable. That is, the resulting signal may still impinge upon the desired hole. Depending on the requirements of the particular system, it may be necessary or desirable to further process the signal to remove these residual low-magnitude events. One approach it to simply specify a bigger hole than is actually required, allowing for some margin of error. Another approach is to perform hole-blowing repeatedly, or iteratively.

In the quadrature domain, sample-rate hole-blowing may be performed one or multiple times (FIG. 16c) and symbol-rate hole-blowing may be performed one or multiple times (FIG. 16d). In the latter case, however, at each iteration, the symbol rate is doubled. For example, in a first iteration, correction symbols may be inserted at T/2. In a second iteration, correction symbols may be inserted at T/4 and 3T/4, etc. One or more iterations of symbol-rate hole-blowing may be followed by one or more iterations of sample-rate hole-blowing (FIG. 16e). (In general, sample-rate hole-blowing cannot be followed by symbol-rate hole-blowing.)

Another alternative is sample-rate hole-blowing in the polar domain.

Polar-Domain Hole-Blowing

The foregoing quadrature-domain hole-blowing techniques preserve ACLR very well at the expense of some degradation in EVM. Other techniques may exhibit a different tradeoff. For example, polar-domain hole-blowing preserves EVM very well at the expense of ACLR. Therefore, in a particular application, quadrature-domain hole-blowing, polar-domain hole-blowing, or a combination of both, may be applied.

The magnitude and phase components of a polar coordinate system can be related to the in-phase and quadrature components of a rectangular coordinate system as

$$ρ ( t ) = \sqrt{{s}_{I}^{2} ( t ) + {s}_{Q}^{2} ( t )}$$

$$θ ( t ) = {tan}^{- 1} ( {s}_{Q} ( t ) / {s}_{I} ( t ) )$$

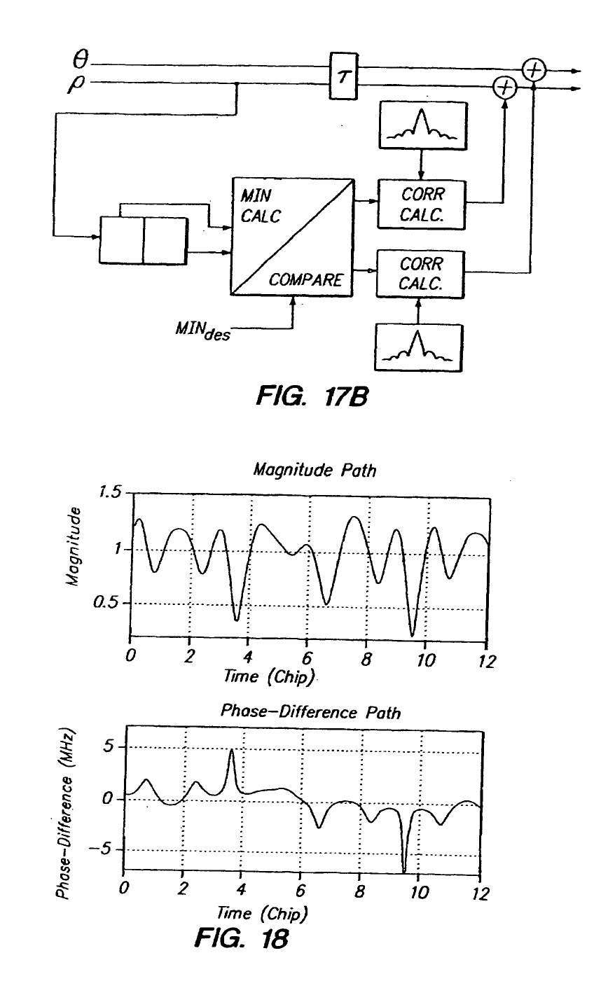

FIG. 17a is a block diagram of a portion of a radio transmitter in which polar-domain nonlinear filtering (i.e., “hole-blowing”) is performed. The diagram shows how magnitude and phase as expressed in the foregoing equations are related to polar-domain nonlinear filtering and the polar modulator.

In FIG. 17a, G represents gain of the polar modulator. In operation, the digital message is first mapped into in-phase and quadrature components in rectangular coordinate system. The in-phase and quadrature components are converted into magnitude and phase-difference by a rectangular-to-polar converter. By knowing the starting point of the phase and the phase-difference in time, the corresponding phase in time can be calculated. This phase calculation is done at a later stage, in the polar modulator. Before feeding the phase-difference to a polar modulator, polar-domain nonlinear filtering is performed.

A more detailed block diagram is shown in FIG. 17b, illustrating a main signal path and a correction signal path for two signal channels, ρ and θ. In the correction path, sequential values of ρ are used to perform a signal minimum calculation and comparison. with a desired minimum. If correction is required based on the comparison results, then for each channel the magnitude of the required correction is calculated. A pulse (or pair of pulses in the case of the θ channel) is scaled according to the required correction and added into the channel of the main path, which will have been delayed to allow time for the correction operations to be performed.

An example of the magnitude and phase components (phase-difference) in polar coordinates is shown in FIG. 18. As can be seen from the plot, when the magnitude dips, there is a corresponding spike (positive or negative) in the phase-difference component.

The spike in the phase-difference component suggests that there is a rapid phase change in the signal, since the phase and phase-difference have the following relationship:
θ(t)=∫\dot{θ}(t)dt

The dip in magnitude and the rapid phase change are highly undesirable as both peaks expand the bandwidth of each polar signal component. The goal of the polar domain nonlinear filtering is to reduce the dynamic range of the amplitude swing as well as to reduce the instantaneous phase change. The dynamic range of the amplitude component and the maximum phase change a polar modulator can handle is limited by the hardware. Polar domain nonlinear filtering modifies the signal before the signal being processed by the polar modulator. This pre-processing is to ensure that the signal dynamic range will not exceed the limit of the implemented hardware capability of the polar modulator, and therefore avoids unwanted signal distortion.

Nonlinear filtering in a polar coordinate system is somewhat more complex than nonlinear filtering in a rectangular coordinate system. Both components (magnitude and phase) in the polar coordinate system have to be handled with care to prevent severe signal degradation.

The following description sets forth how polar-domain nonlinear filtering is performed in an exemplary embodiment. Polar-domain nonlinear filtering is composed of two parts. The first part is nonlinear filtering of magnitude component, and the second part is nonlinear filtering of the phase component (phase-difference). These two parts will each be described in turn.

Nonlinear Filtering of Magnitude Component

If the magnitude dynamic range exceeds the capability of the polar modulator, the output signal will be clipped. This clipping will result in spectral re-growth and therefore greatly increase the adjacent channel leakage ratio (ACLR). One method that can be applied to reduce the dynamic range of the magnitude component is hole-blowing (or nonlinear filtering).

The purpose of this nonlinear filtering of the magnitude component is to remove the low magnitude events from the input magnitude ρ(t), and therefore reduce the dynamic range of the magnitude swing. Assume a threshold (TH_{mag}) for the minimum magnitude; by observing the signal ρ(t), it is possible to obtain the time intervals where the signal falls below the threshold. Assume there are N time intervals where the signal falls below the threshold and that the magnitude minimums for each of these time intervals happen at t₁, . . . , t_{N}, respectively. Therefore, the nonlinear filtering of magnitude component can be expressed as:

$$\hat{ρ} ( t ) = ρ ( t ) + {\sum }_{n = 1}^{N} {b}_{n} {p}_{n} ( t - {t}_{n} )$$

where bₙ and pₙ(t) represent the inserted magnitude and pulse for the n th time interval. The nonlinear filtered signal is composed of the original signal and the inserted pulses. The magnitude of the inserted pulse is given as:
bₙ=TH_{mag}−ρ(tₙ)

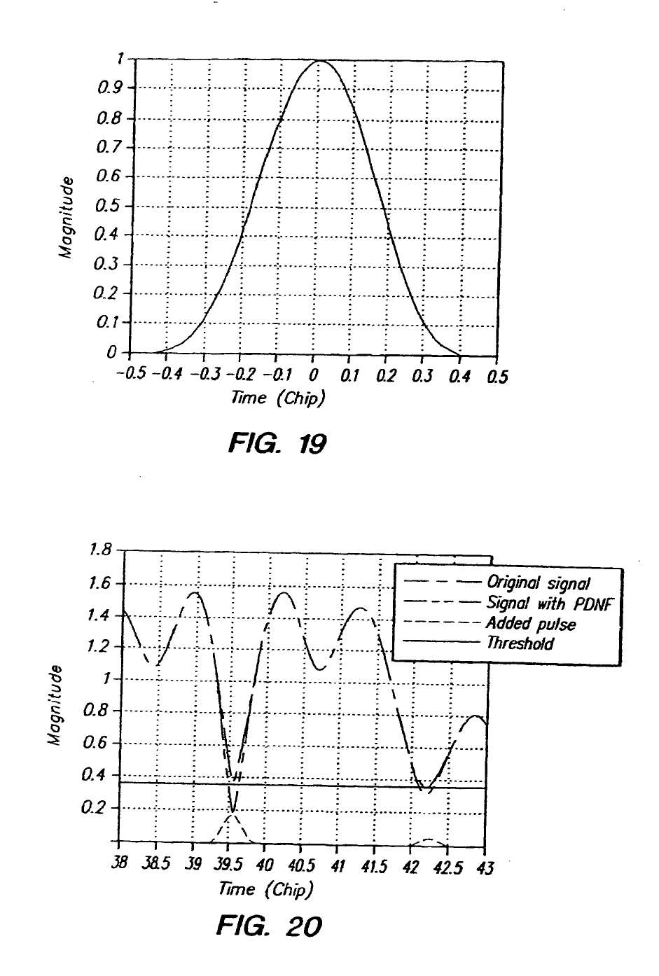

The inserted pulse pₙ(t) has to be carefully chosen so that the signal degradation with respect to ACLR is minimized. It is desirable for the pulse function to have smooth leading and trailing transitions. A suitable pulse (DZ3) is based on McCune's paper entitled “The Derivative-Zeroed Pulse Function Family,” CIPIC Report #97-3, University of California, Davis, Calif., Jun. 29, 1997. The impulse response of the DZ3 pulse is plotted in FIG. 19.

Results of an example for nonlinear filtering of the magnitude component are shown in FIG. 20. As can be seen from the plot, signal intervals where the magnitude dropped below the threshold are compensated by the inserted pulses. As a result, the dynamic range of the magnitude swing is reduced.

Nonlinear Filtering of Phase Component

In an exemplary embodiment, the input to the polar modulator is phase-difference, not phase. A voltage-controlled oscillator (VCO) in the polar modulator integrates the phase-difference and produces the phase component at the output of the polar modulator. The phase-difference is directly related to how fast the VCO has to integrate. If the phase-difference exceeds the capability of the VCO, the output signal phase will lag (or lead) the actual signal phase. As a result, phase jitter will occur if the VCO is constantly unable to keep up with the actual signal phase. This phase jitter will result in constellation rotation, and may therefore severely degrade EVM.

The purpose of the nonlinear filtering of phase component is to suppress large (positive or negative) phase-difference events so that phase accumulation error will not occur. It is important to know that the output of the VCO is an accumulation of the input (phase-difference). Therefore, any additional processing to the phase-difference has to ensure that the phase error will not accumulate. The nonlinear filtering of the phase component described presently carefully modifies the phase-difference in a way that the accumulated phase might deviate from the original phase trajectory from time to time. However, after a certain time interval, it will always merge back to the original phase path.

Nonlinear filtering of the phase component is done by first finding the location where the absolute value of the phase-difference is beyond the integral capability of the VCO. Assume there are a total of M events where the absolute values of the phase-difference are beyond the capability of the VCO, and that the peak absolute value for each event happens at tₘ. Nonlinear filtering of the phase-difference component may then be described by the following expression:

$${\dot{θ}}^{⋒} ( t ) = {\dot{θ}}^{⋒} ( t ) + {\sum }_{m = 1}^{M} {c}_{m} {p}_{p , m} ( t - {t}_{m} )$$

where p_{p,m}(t) is the pulse inserted to the phase-difference component at time tₘ, and cₘ is the corresponding magnitude given by
cₘ=THₚ−\dot{θ}(tₘ)
where THₚ is the threshold for the phase-difference.
The inserted pulse should satisfy the following equation
∫p_{p,m}(t)dt=0

The result of inserting a pulse is basically the same as altering the phase trajectory. However, by inserting pulses that satisfy the above equation, the modified phase trajectory will eventually merge back to the original phase trajectory. This can be seen by the following equation:

$$\int {\dot{θ}}^{⋒} ( t ) ⅆ t = \int \dot{θ} ( t ) ⅆ t + {\sum }_{m = 1}^{M} {c}_{m} {p}_{p , m} ( t ) ⅆ t$$

The second term on the right-hand side will eventually disappear. Therefore, the modified phase trajectory will merge back to the original phase trajectory.

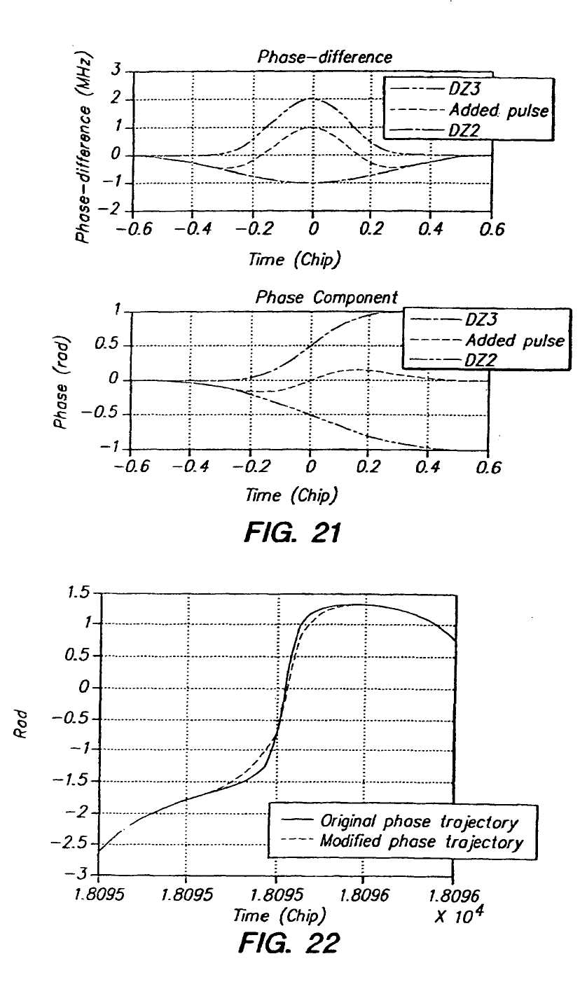

An example of an added pulse pₚ(t) suitable for nonlinear filtering of the phase component is plotted in FIG. 21. Again, it is very important for the pulse function to have smooth leading and trailing transitions. The pulse used for nonlinear filtering at the phase-difference path is composed of two pulses. These two pulses have the same area but different polarity and durations. Therefore, the integration of the combined pulse with respect to time is zero.

Results of an example of nonlinear filtering of the phase-difference component are shown in FIG. 22. As can be seen from the plot, the modified phase trajectory has a smoother trajectory than the original phase trajectory. The modified phase trajectory requires less bandwidth from the VCO than the original phase trajectory.

Polar-domain nonlinear filtering is composed of the filtering of magnitude and phase components. If the nonlinear filtering is done jointly (both magnitude and phase), better spectral roll-off can be achieved. However, each nonlinear filtering operation can also be done independently.

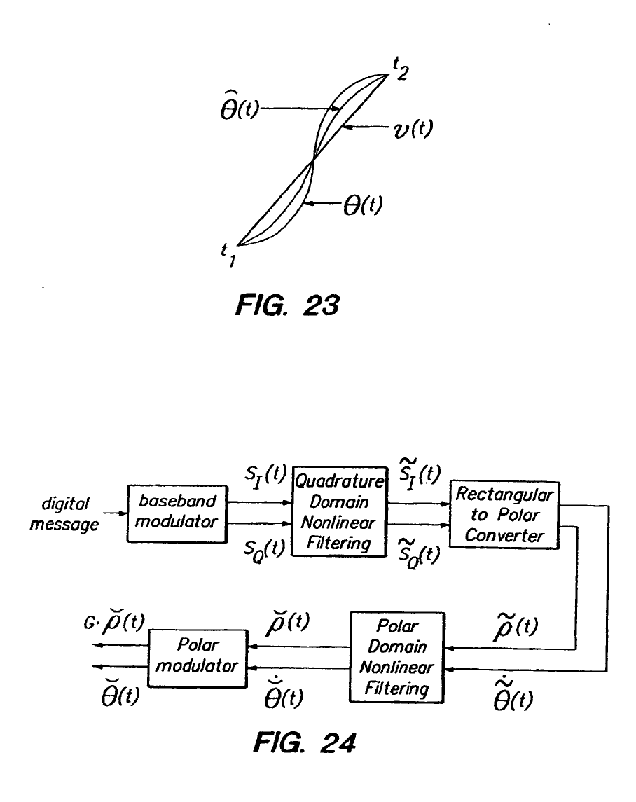

Instead of nonlinear filtering of the phase-difference component, direct nonlinear filtering of the phase component can also be implemented. FIG. 23 shows an example in which the original signal has a steep increase in phase from time t₁ to t₂. One way of reducing the phase change is by interpolating between the straight line v(t) and the original phase path. The interpolation can be expressed as:
\hat{θ}(t)=w(t)θ(t)+(1−w(t))v(t)
where w(t) is a weighting factor. The weighting factor can be a constant or may vary in accordance with DZ3, a Gaussian function, or the like. Again, it is important for the weighting function to have smooth leading and trailing edges.

Polar-domain nonlinear filtering can be used in concatenation with quadrature-domain nonlinear filtering. Such an approach may involve less computational complexity than iterative quadrature-domain nonlinear filtering.

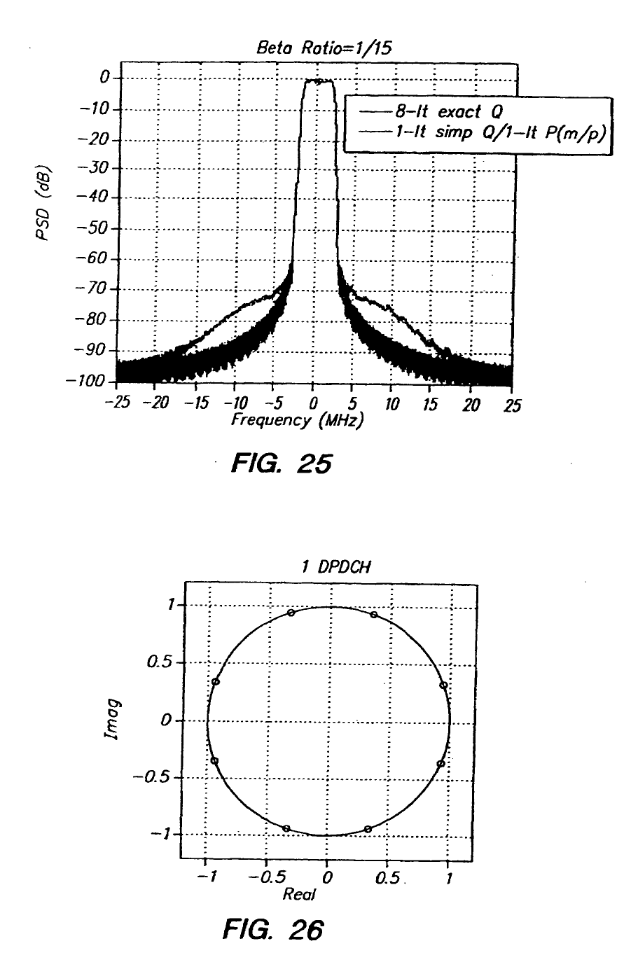

If only one iteration of quadrature-domain nonlinear filtering is performed, low-magnitude, high-phase-variation events may still occur, but with low probability. These low probability events can degrade signal quality if not properly managed. To eliminate these low-probability events, the foregoing polar-domain nonlinear filtering method may be used following a single iteration of quadrature-domain nonlinear filtering, maintaining low EVM and low ACLR. FIG. 24 shows the block diagram for this concatenated system. FIG. 25 shows the PSD of the output signal processed by the quadrature-polar nonlinear filtering module. Curve A represents the signal with eight iterations of quadrature-domain non-linear filtering. Curve B represents the signal with one iteration of quadrature-domain nonlinear filtering followed by one iteration of polar-domain nonlinear filtering. Spectral re-growth is below −60 dB. In addition, good spectral roll-off is achieved.

Reduction of Computational Load for Real-Time Applications

In a practical polar modulator, the hole-blowing algorithm must be implemented in real-time using digital hardware and/or software. Real-time implementation of the exact hole-blowing method presents several challenges. The particular challenges faced are, to some extent, dependent on the overall architecture selected. There are (at least) two alternative architectures for implementing the exact hole-blowing algorithm. In the first architecture, referred to as symbol-rate hole-blowing, corrective impulses are calculated and added to the data stream with appropriate timing, after which pulse shaping is performed. In the second architecture, referred to as sample-rate (or oversampled) hole-blowing, the full pulse-shaped signal is calculated, after which weighted pulses are added to the pulse-shaped signal.

Because of its computational complexity, the exact hole-blowing algorithm described earlier is difficult to implement using digital hardware. In the exact hole-blowing algorithm, arithmetic division, square, and square-root operations are required. These arithmetic operations greatly increase the complexity of the digital hardware and should be avoided if possible. Reduction in computational complexity of the implemented algorithm leads directly to a reduction in hardware complexity. The real-time hole-blowing algorithm described herein requires no division, square, or square-root operations.

Although a real-time hole-blowing algorithm can be implemented in either symbol-rate or sample-rate form, it is generally more desirable to implement symbol-rate hole-blowing. In particular, symbol-rate hole-blowing algorithm allows the digital hardware to be operated at a slower clock speed and does not require as much memory to perform pulse insertion. A symbol-rate real-time hole-blowing algorithm will therefore be described.

Generally speaking, real time hole-blowing algorithm is very similar to the exact hole-blowing algorithm. However, some assumptions and approximations are made in real time hole-blowing algorithm to simplify implementation. In the real-time hole-blowing algorithm, assumptions are made regarding where magnitude minimums are most likely to occur based on the structure of the signal constellation(s). The assumption allows for determination of where to insert the pulse, if needed, without calculating the entire signal magnitude. In addition, the arithmetic operations in exact bole-blowing algorithm are greatly simplified by normalizing the expression \sqrt{Δx²+Δy²} to one. This normalization eliminates the need for division, square, and square-root operations.

The differences between the real-time and exact hole-blowing algorithms may be appreciated by considering answers to the following questions:
1. What are the potential timings for the low-magnitude events?
2. What are the values of magnitude minimums, and how can they be calculated efficiently and accurately?
3. What are the in-phase and quadrature correction weights of the magnitude minimum if a signal falls below the prescribed threshold?
   These questions will be addressed using the UMTS signal as an example.
   1. What are the Potential Timings for the Low-Magnitude Events?

If the timings of the magnitude minimums can be estimated based on the input data bits, then it is not necessary to calculate the whole waveform in order to obtain the magnitude minimums. This shortcut affords a great saving in computation. The locally linear model can be used to calculate the minimums with great accuracy if the approximate timing for low-magnitude events is known.

As previously described, the minimum magnitudes for a bandlimited QPSK signal usually occur close to half-symbol instance (nT+T/2). This assumption is supported by the histogram in FIG. 6. This assumption can also be applied to higher-order pulse-shaped PSK signals whose constellation points lie on the same circle. A good example for this type of signal is the UMTS signal with one active data channel. FIG. 26 shows an example of the UMTS signal constellations with one active data channel. As can be seen from the plot, all constellation points lie on the same circle. If a histogram is constructed for this particular signal, it may be seen that the timings for the low-magnitude events are very likely to happen at every half-symbol instance. Therefore, for this particular signal, it is assumed that the timings for the low-magnitude events will occur at time nT+T/2, where n is an integer.

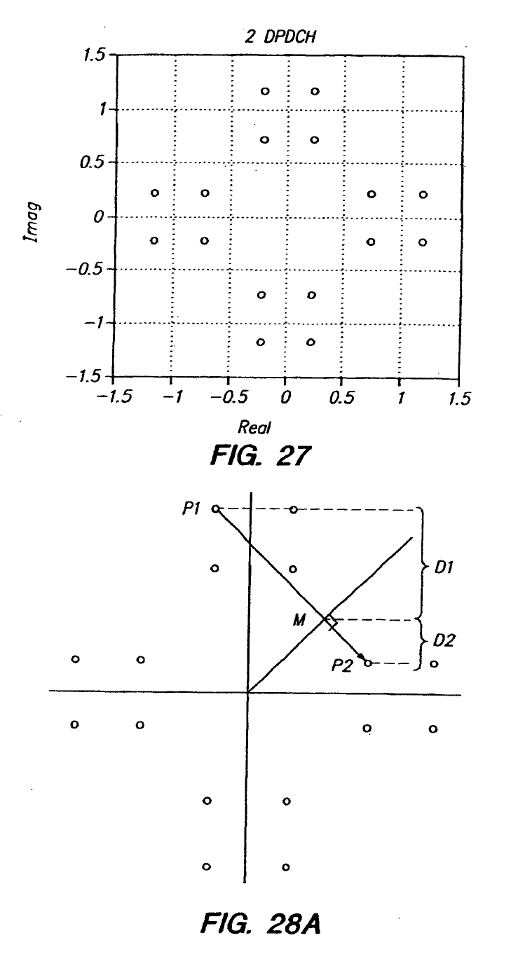

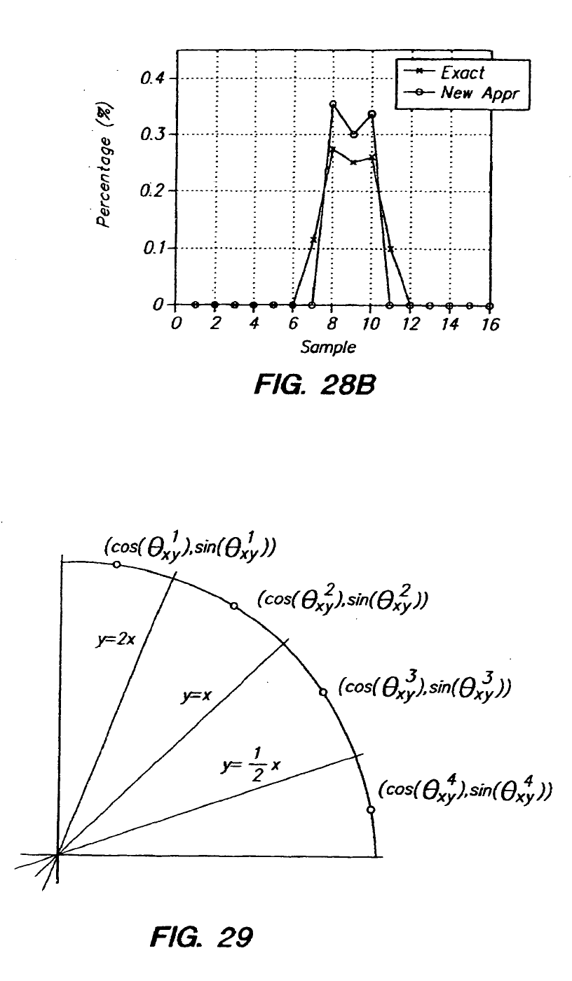

The above assumption will not be true in the case of a more complex signal constellation. FIG. 27 shows an example of the UMTS signal constellations with two active data channels. As can be seen from the plot, not all the constellation points lie on the same circle. The algorithm used to find the magnitude minimums for a more complex signal constellation is illustrated in FIG. 28a, and described as follows:
1. If the signal transitions from constellation point P1 at time nT and ends at point P2 at time (n+1)T, a straight line is drawn connecting the two points. This line is denoted as the first line.
2. A second line is drawn perpendicular to the line that connects P1 and P2. The second line includes the origin and intersects the first line at point M.
3. The second line divides the first line into two sections whose length are proportional to D1 and D2, respectively. The timing for the low-magnitude event is approximately nT+D1/(D1+D2)T.
4. If the second line and the first line do not intersect, there is no need for pulse insertion.
5. Having determined where the magnitude minimums are most likely to occur, the locally linear model is then used to calculate the local magnitude minimums.

With the above algorithm, a look-up table can be built for different signal constellations. The size of the look-up table can be reduced if the constellation points are symmetrical to both x and y axis. A special case of the foregoing algorithm occurs where D1 always equal to D2, corresponding to the UMTS signal with one active data channel. Therefore, the magnitude minimums for one active data channel always happens close to time nT+T/2. The above algorithm for finding the approximate locations of magnitude minimums can also be generalized to signals with more complex constellations.

FIG. 28b shows the probability density function, by sample interval (assuming 15 samples per symbol), of minimum magnitude events where correction is required, for both the exact method described earlier and the real-time approximation just described. Note the close correspondence between the two functions.

2. What are the Values of the Magnitude Minimums, and how can they be Calculated Efficiently and Accurately?

With the knowledge of the timing where the magnitude minimums are likely to occur, the locally linear model is then used to calculate the magnitude minimums. A determination must be made whether the magnitude of the signal falls below the prescribed threshold. If the magnitude falls below the prescribed threshold, in-phase and quadrature correction weights, c_{I} and c_{Q}, for the inserted pulse have to be calculated.

From the exact hole-blowing algorithm, the magnitude minimum can be calculated by the following equation:

$${ρ}_{min} = \frac{\vert y 1 Δ x - x 1 Δ y \vert}{\sqrt{Δ {x}^{2} + Δ {y}^{2}}}$$

where x1 and y1 are the in-phase and quadrature samples of the signal at time t1, and t1 is the time where the magnitude minimums are most likely to occur.

The equation above involves one division, one square-root operation, two square operations, as well as several other operations—multiplication, addition and subtraction. The computational complexity can be reduced by normalizing the denominator of the above equation.

Let the vector (Δx, Δy) be expressed as:
Δx=ρ_{xy} cos(θ_{xy})
Δy=ρ_{xy} sin(θ_{xy})
where ρ_{xy} and θ_{xy} are the magnitude and phase of the vector (Δx, Δy). Then, the minimum magnitude of the signal can be expressed as

$$\begin{matrix}{ρ}_{min} = \frac{\vert y 1 Δ x - x 1 Δ y \vert}{\sqrt{Δ {x}^{2} + Δ {y}^{2}}} \\ = \frac{{ρ}_{xy} \vert y 1 cos ( {θ}_{xy} ) - x 1 sin ( {θ}_{xy} ) \vert}{{ρ}_{xy} \sqrt{{cos}^{2} ( {θ}_{xy} ) + {sin}^{2} ( {θ}_{xy} )}} \\ = \vert y 1 cos ( {θ}_{xy} ) - x 1 sin ( {θ}_{xy} ) \vert\end{matrix}$$

With this normalization, no division, square, or square-root operation is required. In addition, it is not necessary to know ρ_{xy}. However, the values of sin(θ_{xy}) and cos(θ_{xy}) are needed. Therefore, given a vector (Δx, Δy), a way is needed to obtain (sin(θ_{xy}), cos(θ_{xy})) efficiently.

Two ways will be described to evaluate sin(θ_{xy}) and cos(θ_{xy}) with relatively low hardware complexity. The first one uses a line-comparison method, and the second one uses the CORDIC (Coordinate Rotation for Digital Computer) algorithm.

First, consider the approximation of sin(θ_{xy}) and cos(θ_{xy}) using a line-comparison method. As can be seen from FIG. 29, lines with a function of y=Mx partition the first quadrant into several sub-sections. By comparing the point (|Δx|,|Δy|) against the lines y=Mx, the sub-section that the point (|Δx|,|Δy|) falls into can be determined. Any point within a certain sub-section is represented by a pre-normalized point (sin(θ_{xy}ⁱ), cos(θ_{xy}ⁱ)), where i denotes the section the point (|Δx|,|Δy|) belongs to.

The details of the algorithm are described as fellows:

1. First, convert the vector (|Δx|,|Δy|) into the first quadrant (|Δx|,|Δy|).

2. Compare |Δy| with M|Δx| where M is positive.

3. If |Δy| is greater than M|Δx|, then (|Δx|,|Δy|) is located at the left side of the line y=Mx

4. If |Δy| is smaller than M|Δx|, then (|Δx|,|Δy|) is located at the right side of the line y=Mx.

5. Based on the above comparisons with different lines, the sub-section the point (|Δx|,|Δy|) belongs to can be located. Assuming the point belongs to section i, then the vector (sin(θ_{xy}), cos(θ_{xy})) can be approximated by the vector (sign(Δx)*sin(θ_{xy}ⁱ), sign(Δy)*cos(θ_{xy}ⁱ)).

A table is used to store the pre-calculated values of (sin(θ_{xy}ⁱ), cos(θ_{xy}ⁱ)). If a total of W lines are used for comparison, there will be (W+1) sub-sections in the first quadrant. As a result, the whole vector plane is being divided into 4*(W+1) sub-sections.

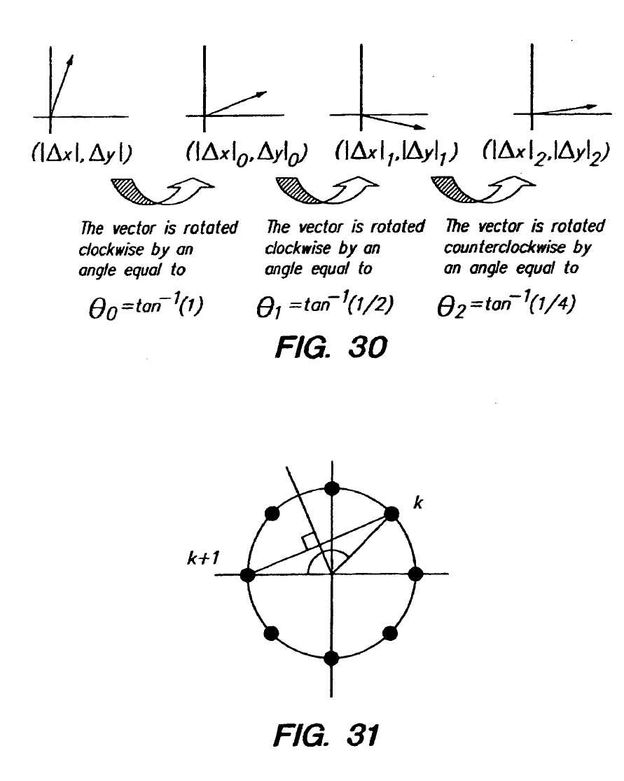

The second method used to approximate (sin(θ_{xy}), cos(θ_{xy})) is a CORDIC-like algorithm. This method is similar to the line-comparison method. However, the CORDIC-like algorithm partitions the vector plane more equally. A more detailed description of the algorithm is presented as follows and is illustrated in FIG. 30:

1. First, convert the vector (Δx, Δy) into the first quadrant (|Δx|,|Δy|).

2. Second, rotate the vector (|Δx|,|Δy|) clock-wise with an angle Θ₀=⁻¹(1). The vector after the angle rotation is denoted as (|Δx|₀,|Δy|₀).

3. Let i=1.

4. If |Δy|ᵢ₋₁ is greater than 0, rotate the vector (|Δx|₀,|Δy|₀) clockwise with an angle Θ₀=⁻¹(2⁻ⁱ). Otherwise, rotate the vector counter-clockwise with an angle of Θᵢ. The vector after the angle rotation is (|Δx|ᵢ,|Δy|ᵢ)

5. Let i=i+1.

6. Repeat steps 4 and 5 if needed.

7. Assume a total of K vector rotations are performed. This algorithm partitions the first quadrant into 2ˆk sub-sections. The sign of |Δy|₀, |Δy|₁, . . . , |Δy|_{K-1} can be used to determine which of the 2ˆk sub-sections the vector (|Δx|,|Δy|) belongs to.

8. A table filled with pre-quantized and normalized values is then used to approximate the vector (|Δx|,|Δy|).

9. If the look-up table gives a vector of (sin(θ_{xy}ⁱ), cos(θ_{xy}ⁱ)) for vector (|Δx|,|Δy|), then (sin(θ_{xy}), cos(θ_{xy})) can be approximated by the vector (sign(Δx)*sin(θ_{xy}ⁱ), sign(Δy)*cos(θ_{xy}ⁱ)).

The vector rotation in the CORDIC algorithm is carefully done so that the vector rotation is achieved by arithmetic shifts only. This leads to a very efficient structure. The accuracy of the approximation can be improved by going through more CORDIC iterations. If a total of two vector rotations are performed, the resulting partition of the first quadrant is similar as in the line-comparison method shown in FIG. 29.

The normalization of the expression \sqrt{Δx²+Δy²} and the efficient algorithms to approximate (sin(θ_{xy}), cos(θ_{xy})) greatly reduce the computational complexity of the locally minimum method. Using these methods, ρₘᵢₙ may be readily evaluated. If the magnitude minimum ρₘᵢₙ falls below the threshold ρ_{desired}, a pulse insertion will be performed based on the hole-blowing algorithm. This leads to the third question:

3. What are the In-Phase and Quadrature Correction Weights if the Magnitude Minimum of the Signal Falls Below the Prescribed Threshold?

Similar techniques can be applied to the calculation of sin(θ) and cos(θ) by replacing Δx with Δx=ρ_{xy} cos(θ_{xy}) and Δy with Δy=ρ_{xy} sin(θ_{xy}), as follows:

$$\begin{matrix}sin θ = \frac{Δ \times sign ( y 1 Δ x - x 1 Δ y )}{\sqrt{Δ {x}^{2} + Δ {y}^{2}}} \\ = \frac{{ρ}_{xy} cos ( {θ}_{xy} ) sign ( y 1 Δ x - x 1 Δ y )}{{ρ}_{xy} \sqrt{{cos}^{2} ( {θ}_{xy} ) + {sin}^{2} ( {θ}_{xy} )}} \\ = cos ( {θ}_{xy} sign ( y 1 Δ x - x 1 Δ y ) \\ cos θ = - sin ( {θ}_{xy} ) sign ( y 1 Δ x - x 1 Δ y )\end{matrix}$$

With the above simplification, the in-phase and quadrature correction weights, c_{I} and c_{Q} can be calculated easily with simple subtraction and multiplication:
c_{I}=(ρ_{desired}−ρₘᵢₙ)cos θ
c_{Q}=(ρ_{desired}−ρₘᵢₙ)sin θ
Summary of the Real Time Hole-Blowing Algorithm

To facilitate real-time implementation, a novel approach is taken to estimate the timings for the low-magnitude events. Also, the locally-minimum method is greatly simplified by normalizing the expression \sqrt{Δx²+Δy²}. As a result, no division, square operation, nor square-root operation are required.

Two methods are being proposed to evaluate (sin(θ_{xy}), cos(θ_{xy})) given the vector (Δx, Δy). The first one is the line-comparison method, and the second one is the CORDIC-like algorithm. The implementation complexities of the above two methods are generally low since only arithmetic shifts and comparisons are needed.

### APPENDIX 1

A1.0 Analysis of the O'Dea Hole-Blowing Methods

In this Appendix, a detailed analysis is presented of the hole-blowing methods proposed in U.S. Pat. Nos. 5,696,794 and 5,805,640. These two patents are very similar and are therefore treated simultaneously. The main difference is that the former patent (U.S. Pat. No. 5,696,794) modifies the symbols to be transmitted, while the latter patent (U.S. Pat. No. 5,805,640) adds pulses at T/2 symbol timing instants. For brevity, patent U.S. Pat. No. 5,696,794 will be referred to as the symbol rate method, and patent U.S. Pat. No. 5,805,640 will be referred to as the T/2 method. An overview of both methods is first presented, followed by an examination of performance with two different signal modulations. The first test signal is π/4 QPSK with zero-ISI raised cosine pulse shaping. This is the modulation employed in the two patents. The second test signal is a UMTS 3GPP uplink signal with one active DPDCH and a DPDCH/DPCCH amplitude ratio of 7/15. UMTS uses square-root raised-cosine pulse shaping with 0.22 rolloff characteristic.

A1.1 Overview of the O'Dea Hole-Blowing Algorithms

The term “half-symbol timing” is defined to be those time instants that are exactly halfway between symbol times. That is, if the PAM signal is modeled as

$$s ( t ) = {\sum }_{k} {a}_{k} p ( t - kT )$$

where T is the symbol period and p(t) is the pulse shape, then the half-symbol times correspond to t=kT+T/2 where k is an integer. For clarity of presentation, it will be assumed that the maximum value of p(t) has been normalized to unity.

Both methods test for the existence of undesirable low-power events by measuring the signal magnitude at the half-symbol time instants, and comparing this value to some desired minimum magnitude mag_d:
mag_{—}s=|s(kT+T/2)|≦vmag_{—}d

Both patents use the same method to calculate the phase of the corrective pulse(s). Assume that the low-magnitude event occurs between symbols k and k+1. First, determine the so-called phase rotation θᵣₒₜ, which is simply the change in phase in the transition from symbol k to symbol k+1, as illustrated in FIG. 31. The corrective phase θ_{adj} is given by

$${θ}_{adj} = {θ}_{k} + \frac{{θ}_{rot}}{2}$$

Where θₖ is the phase of the kth symbol. A vector with phase equal to the adjustment phase is orthogonal to a straight line drawn from symbol k to symbol k+1, as illustrated in FIG. 31. Note that since there are a finite number of possible phase rotations, there are also a finite number of possible phase adjustments, so that explicit calculation of the rotation phase is not necessary.

If the symbol rate approach (U.S. Pat. No. 5,696,794) is used, the two symbols adjoining the low-magnitude event (i.e., symbols k and k+1) are modified by the addition of a complex scalar. The magnitude of this complex scalar is given by
m=0.5(mag_{—}d−mag_{—}s)/p_{mid}
where p_{mid} is the amplitude of the pulse shaping filter at t=T/2. (The rationale for calculating the magnitude of the correction in this manner, however, is unclear.) The complex scalar adjustment is then
c_{adj}=m exp(jθ_{adj})
and the resulting modified symbols are given by
ãₖ=aₖ+c_{adj}
ãₖ₊₁=a_{c+1}+c_{adj}

Note that both symbols are modified in the same manner.

Thus, a noise component is added to the signal by intentional relocation of the information symbols {aₖ}. This can “confuse” any equalizer at the receiver, which will expect that any signal distortion is due to the channel.

If the T/2 approach (U.S. Pat. No. 5,805,640) is used, a complex scalar is added to the symbol stream, before pulse-shaping, at the appropriate half-symbol time instants. When a low magnitude event is detected at t kT+T/2, a complex symbol with magnitude
m=(mag_{—}d−mag_{—}s)
and phase equal to θ_{adj} (given above) is added at t=kT+T/2.
This restriction to T/2 insertion timing limits this method to circular signal constellations.

One additional difference between the symbol rate method and the T/2 method is that the symbol rate method is intended to be applied iteratively until the signal magnitude does not drop below some threshold. There is no mention of an iterative process in the T/2 patent.

A1.2 Performance with π/4 OPSK

Consider now the performance of the known hole-blowing algorithms relative to the disclosed “exact” hole-blowing method when the targeted signal is π/4 QPSK. It is interesting to note that this signal has a “hole” in its constellation if the rolloff is high, e.g., α=0.5. A rolloff of 0.22 was chosen so that the signal would not have a pre-existing hole.

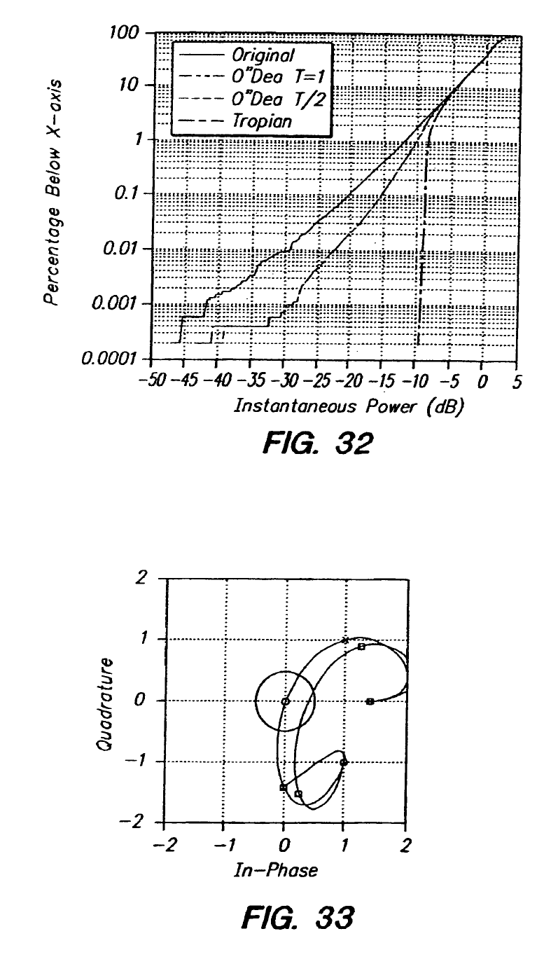

FIG. 32 shows the CDF obtained from the disclosed method and the two known methods with the aforementioned p/4 QPSK signal. The desired minimum power level was set at 9 dB below RMS. These simulation results are based on 16384 symbols with 32 samples/symbol. The figure clearly shows that the exact method is much more effective than either of the known methods. It is also evident that both known methods perform similarly. This is not surprising given the similarity of the two approaches.

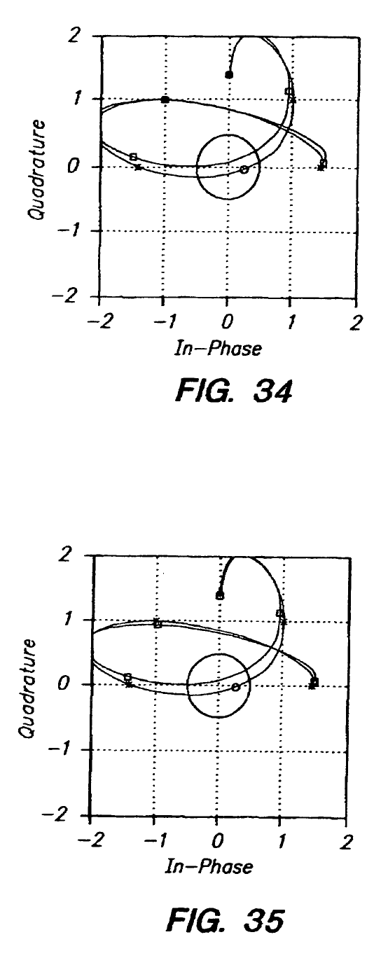

Some explanation of the performance of the known methods as shown in FIG. 32 is in order. It was noted earlier that there are sources of error possible in calculation of both the magnitude and phase of the correction pulses. FIG. 33 shows an example where the prior-art symbol rate method works fairly well. The signal envelope is not pushed completely out of the desired hole, but the method is performing more-or-less as intended. In contrast, FIG. 34 shows an example where the prior-art symbol rate method does not perform well. This example illustrates error in both the magnitude and phase of the corrective pulses. In this example, the trace passes on the “wrong side” of the origin relative to the assumptions made in calculating the correction phase. Thus the trace is pushed in the wrong direction. Furthermore, it is evident from this example that the magnitude at T/2 is not the minimum magnitude, so that even if the phase had been calculated correctly, the signal would not have been pushed far enough.

FIG. 35 shows an example where the prior-art T/2 method does not perform well. (The segment shown in FIG. 35 is the same segment of the signal shown in FIG. 34, where the symbol rate method did not perform well.) Comparing FIG. 34 and FIG. 35, it is clear that the two methods yield nearly identical traces. It can be seen that the symbol rate method only alters the symbols adjacent to the low-magnitude event, while the T/2 method affects more symbols.

A1.3 Performance with a 3GPP Uplink Signal

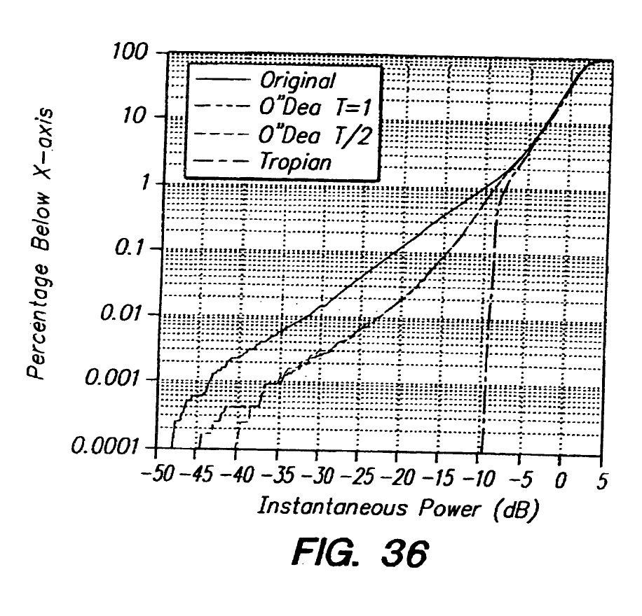

Consider now the performance of the known methods with a more realistic signal, that being a 3GPP uplink signal with one active DPDCH and an amplitude ratio of 7/15. FIG. 36 shows the CDF's obtained with the disclosed exact method and with the known hole-blowing methods when applied to one frame (38400 chips) of the signal with 32 samples/chip. It is clear that the exact correction method greatly outperforms the known methods, and that the known methods perform comparably.

What is claimed:

1. An apparatus for reducing the amplitude dynamic range of a communications signal, comprising:
a baseband modulator operable to receive a digital message and generate a signal having a plurality of symbols;
an analyzer operable to generate a plurality of correction pulses at moments in time when the magnitude of said signal having a plurality of symbols falls below a predetermined threshold;
a nonlinear filter configured to receive said plurality of correction pulses and generate a correction signal, which when combined with said signal having a plurality of symbols, forms a modified communications signal having a reduced amplitude dynamic range,
wherein said nonlinear filter is configured to condition said plurality of correction pulses to reduce the degree by which said plurality of correction pulses contributes to in-channel distortion of said modified communications signal.

2. The apparatus of claim 1 wherein said nonlinear filter is further configured to condition said plurality of correction symbols so that said modified communications signal satisfies a predetermined power criterion of an adjacent communications channel.

3. The apparatus of claim 1 wherein said in-channel distortion is characterized by the error vector magnitude (EVM) of the modified communications signal measured at a receiver adapted to receive said modified communications signal.

4. The apparatus of claim 1 wherein reducing the dynamic range of said communications signal by said nonlinear filter is performed by reducing the average-to-minimum magnitude ration (AMR) of said communications signal.

5. The apparatus of claim 1 wherein said nonlinear filter is configured to approximate a reference pulse at a sampled output of a matched filter of a receiver adapted to receive said communications signal, wherein said reference pulse has an energy that is distributed substantially evenly in frequency.

6. The apparatus of claim 1 wherein it is assumed that said moments in time occur halfway between transitions temporally adjacent symbols of said plurality of symbols.

7. A method of optimizing perturbation pulses to be combined with a communications signal, to form a perturbed communications signal having a reduced amplitude dynamic range, said method comprising:
defining an error function comprising the difference between a summation of perturbation pulse samples and a summation of reference pulse samples; and
minimizing said error function to determine optimized pulses, which when combined with said communications signal, do not substantially increase in-channel distortion of said communications signal.

8. The method of claim 7 wherein minimizing said error function is performed subject to a predetermined maximum allowable out-of-channel power condition.

9. An apparatus for conditioning a communications signal, comprising:
a modulation and signal conditioning apparatus configured to receive a communications signal and generate a sequence of symbols;
a first filter disposed in said main path operable to generate a first pulse-shaped signal from said sequence of symbols;
means for determining low magnitude events in said first pulse-shaped signal;
a second filter disposed in said auxiliary path operable to generate a perturbation signal having pulses that correspond to the determined low magnitude events; and
means for combining the first pulse-shaped signal with the perturbation signal to generate a perturbed signal having an in-channel distortion that is not substantially different from an in-channel distortion of the unperturbed first pulse-shaped signal.

10. The apparatus of claim 9 wherein the perturbed signal has a lower dynamic range than the unperturbed first pulse-shaped signal.

11. The apparatus of claim 9 wherein said second filter is configured to ensure that the perturbed signal satisfies a maximum allowable out-of-channel power requirement.

12. The apparatus of claim 9 wherein said perturbation signal, when combined with said first pulse-shaped signal, does not substantially contribute to an increase in in-channel distortion.

13. The apparatus of claim 9 wherein said means for determining low magnitude events in said sequence of symbols assumes that the low magnitude events occur at times t=nT/2, where n is an integer and T represents the symbol period.

14. A method of reducing signal degradation introduced by reducing the dynamic range of a communications signal, comprising:
determining a time when a transition between a first symbol and a second symbol in a sequence of modulation symbols is at its lowest magnitude;
forming a pulse-shaped signal based on said sequence of modulation symbols using a first filter;
forming a perturbation pulse using a second filter; and
inserting said perturbation pulse in the pulse-shaped signal at the time when the transition between the first and second symbols is at its lowest magnitude, to reduce the dynamic range of the pulse-shaped signal,
wherein said second filter is designed to minimize the amount by which the perturbation pulse contributes to an in-channel distortion of said pulse-shaped signal.

15. The method of claim 14 wherein said second filter is further designed to ensure that a predetermined out-of-channel power threshold is not exceeded.

16. The method of claim 14 wherein determining the time when a transition between the first and second symbols is at its lowest magnitude comprises assuming that the lowest magnitude occurs at a time halfway between the transition between the first and second symbols.

17. A method of reducing signal degradation introduced by reducing the average-to-minimum amplitude ratio (AMR) of a communications signal, comprising:
identifying a time when a communications signal falls below or is likely to fall below a predetermined magnitude minimum;
forming a corrective pulse; and
inserting the corrective pulse in the temporal vicinity of the identified time to form a corrected communications signal having an AMR which is lower than the said communications signal,
wherein forming said corrective pulse includes conditioning the corrective pulse to minimize the amount of in-channel distortion the corrective pulse introduces to the communications signal by its insertion while substantially preserving an out-of-band measure of quality of the communications signal.

18. A signal conditioning apparatus for a wireless communications device, comprising:
a baseband modulator configured to map a digital sequence onto a signal constellation having a plurality of constellation points;
a first filter having an impulse response configured to receive a sequence of symbols corresponding to said constellation point and generate an unperturbed communications signal;
means for determining instants in time when said unperturbed communications signal falls below or is likely to fall below a predetermined magnitude threshold and generate a perturbation sequence;
a second filter having an impulse response different from the impulse response of said first filter, said second filter configured to receive said perturbation sequence and generate a perturbation signal v(t); and
a combiner operable to combine said unperturbed communications signal with said perturbation signal to produce a perturbed communication signal characterized by an average-to-minimum amplitude ratio (AMR) that is smaller than an AMR of said unperturbed communications signal,
wherein said second filter is configured to operate on said perturbation sequence to provide a perturbation signal that does not substantially introduce distortion into a communications channel occupied by said unperturbed communications signal.

19. The signal conditioning apparatus of claim 18 wherein said second filter is further configured to condition said perturbation sequence so that the perturbed communication signal satisfies a predetermined out-of-channel power leakage condition.
